(19) United States
(12) Patent Application Publication
(10) Pub. No.: US 2024/0413801 A1
(43) Pub. Date: Dec. 12, 2024

(54) VOLTAGE-MODE FILTERS WITH OUTPUT IMPEDANCE NEUTRALIZATION

(71) Applicant: International Business Machines Corporation, Armonk, NY (US)

(72) Inventors: Sudipto Chakraborty, Plano, TX (US); John Francis Bulzacchelli, Somers, NY (US); Adou Sangbone Joseph Desire Assoa, Atlanta, GA (US)

(21) Appl. No.: 18/330,429

(22) Filed: Jun. 7, 2023

(51) Int. Cl. H03F 3/45; G06N 10/40; H03F 1/08

(52) U.S. Cl. CPC H03F 3/45659; G06N 10/40; H03F 1/086; H03F 3/45264; H03F 2200/451

(57) ABSTRACT

A device comprises a differential voltage-mode filter circuit comprising first and second voltage-mode filter circuits, and a neutralization network. The first and second voltage-mode filter circuits each comprise a unity gain buffer having a nonzero output impedance. The neutralization network comprises a first neutralization impedance circuit which couples an input of the first voltage-mode filter circuit to an output of the second voltage-mode filter circuit, and a second neutralization impedance circuit which couples an input of the second voltage-mode filter circuit to an output of the first voltage-mode filter circuit. The neutralization network is configured to correct a frequency response of the first and second voltage-mode filter circuits by at least one of cancelling and compensating for at least one transmission zero of a transfer function of each of the first and second voltage-mode filter circuits, which results from the nonzero output impedance of the respective unity gain buffers.

### BACKGROUND

This disclosure relates generally to voltage-mode filters and, in particular, voltage-mode baseband filters for radio frequency (RF) signal generators, such as arbitrary waveform generator (AWG) systems. An RF signal generator may be implemented as a Cartesian architecture with quadrature phases, in which baseband in-phase (I) and quadrature-phase (Q) signals are filtered, and upconverted via I/Q-channel mixers to an RF signal using a single-sideband (SSB) modulation system. Such RF signal generators are utilized for applications such as, e.g., wireless transmitters, and generating control pulses for quantum bits (qubits) in a quantum computing system, etc. In particular, in quantum computing applications, AWG systems that are capable of generating RF control pulses with variable amplitude and low distortion are desirable for controlling qubits of a quantum processor. In addition, minimizing power consumption of an AWG system is of critical importance, especially in the context of cryogenic RF signal generation for qubit control.

An RF signal generator can have various signal processing stages that are implemented using current-mode circuitry. For example, an RF signal generator can be implemented using a current-mode baseband filter which interfaces to a current-mode RF output stage. The current-mode circuitry can provide a favorable tradeoff between power and performance. For example, the current-mode circuitry of an RF output stage allows current reuse in which the bias current of one stage is shared with another stage to improve power efficiency. Moreover, a current-mode baseband filter can provide a high performance with regard to frequency response (e.g., high out-of-band rejection). On the other hand, current-mode circuits often comprise stacked transistor architectures which may require moderate quiescent currents and high supply voltages (and therefore higher power dissipation) to provide the necessary headroom to operate the stacked transistors in saturation mode.

On the other hand, voltage-mode baseband filters can be utilized to filter baseband signals that are applied to an RF output stage. As compared to current-mode baseband filters, the voltage-mode baseband filters can have architectures which require lower quiescent current and voltage headroom and, thus, can be operated with relatively smaller supply voltages and with lower power dissipation. With certain voltage-mode filter architectures which implement an active output buffer stage that is operated in a low power implementation (e.g., with low quiescent currents), a nonzero output impedance of the buffer stage can lead to a poor filter response (e.g., poor out-of-band rejection), which can be unacceptable for various applications such as quantum computing applications.

### SUMMARY

Exemplary embodiments of the disclosure include voltage-mode filter circuit architectures for use with RF signal generator systems, such as arbitrary waveform generator systems. The exemplary voltage-mode filter circuits provide low-power filter architectures which can be utilized with reduced supply voltage levels for low power consumption, and which implement impedance neutralization networks that are configured to neutralize output impedances of the voltage-mode filter circuits and thereby enhance a frequency response of the voltage-mode filter circuits, e.g., provide increased out-of-band rejection.

In an exemplary embodiment, a device comprises a differential voltage-mode filter circuit comprising a first voltage-mode filter circuit, a second voltage-mode filter circuit, and a neutralization network. The first voltage-mode filter circuit and the second voltage-mode filter circuit each comprise a unity gain buffer having a nonzero output impedance. The neutralization network comprises a first neutralization impedance circuit which couples an input node of the first voltage-mode filter circuit to an output node of the second voltage-mode filter circuit, and a second neutralization impedance circuit which couples an input node of the second voltage-mode filter circuit to an output node of the first voltage-mode filter circuit. The neutralization network is configured to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

Advantageously, an output impedance neutralization network compensates for the negative effects on a frequency response of the first and second voltage-mode filter circuits as a result of the nonzero output impedance of the respective unity gain buffers, and thereby enables the implementation of an ultra-low power, high-bandwidth differential voltage-mode filter with an improved frequency response (e.g., higher out-of-band rejection) despite the nonzero output impedance of the unity gain buffers of the first and second voltage-mode filter circuits of the differential voltage-mode filter circuit.

Another exemplary embodiment includes a device which comprises a digital-to-analog converter circuit, a differential voltage-mode filter circuit, and a current-mode output circuit. The digital-to-analog converter circuit comprises an output interface that is configured to generate a differential analog voltage signal comprising a first voltage signal and a second voltage signal which are complementary voltage signals. The differential voltage-mode filter circuit is configured to filter the differential analog voltage signal and output a filtered differential analog voltage signal comprising a first filtered voltage signal and a second filtered voltage signal which are complementary filtered voltage signals. The current-mode output circuit is coupled to the differential voltage-mode filter circuit, and is configured to convert the first filtered voltage signal and the second filtered voltage signal into a first current signal and a second current signal, respectively, for processing by the current-mode output circuit. The differential voltage-mode filter circuit comprises a first voltage-mode filter circuit configured to filter the first voltage signal, a second voltage-mode filter circuit configured to filter the second voltage signal, and a neutralization network comprising a first neutralization impedance circuit and a second neutralization impedance circuit. The first voltage-mode filter circuit and the second voltage-mode filter circuit each comprise a unity gain buffer having a nonzero output impedance. The first neutralization impedance circuit couples an input node of the first voltage-mode filter circuit to an output node of the second voltage-mode filter circuit, and the second neutralization impedance circuit couples an input node of the second voltage-mode filter circuit to an output node of the first voltage-mode filter circuit. The neutralization network is configured to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

Another exemplary embodiment includes a system which comprises a radio frequency signal generator which is configured to convert a baseband signal to a radio frequency signal. The radio frequency signal generator comprises a digital-to-analog converter circuit, a differential voltage-mode filter circuit, and a current-mode radio frequency output circuit. The digital-to-analog converter circuit comprises an output interface that is configured to generate a differential baseband voltage signal comprising a first baseband voltage signal and a second baseband voltage signal which are complementary baseband voltage signals. The differential voltage-mode filter circuit is configured to filter the differential baseband voltage signal and output a filtered differential baseband voltage signal comprising a first filtered baseband voltage signal and a second filtered baseband voltage signal, which are complementary filtered baseband voltage signals. The current-mode radio frequency output circuit is coupled to the differential voltage-mode filter circuit, and is configured to convert the first filtered baseband voltage signal and the second filtered baseband voltage signal into a first baseband current signal and a second baseband current signal, respectively, for processing by the current-mode radio frequency output circuit to generate the radio frequency signal. The differential voltage-mode filter circuit comprises a first voltage-mode filter circuit configured to filter the first baseband voltage signal, a second voltage-mode filter circuit configured to filter the second baseband voltage signal, and a neutralization network comprising a first neutralization impedance circuit and a second neutralization impedance circuit. The first voltage-mode filter circuit and the second voltage-mode filter circuit each comprise a unity gain buffer having a nonzero output impedance. The first neutralization impedance circuit couples an input node of the first voltage-mode filter circuit to an output node of the second voltage-mode filter circuit, and the second neutralization impedance circuit couples an input node of the second voltage-mode filter circuit to an output node of the first voltage-mode filter circuit. The neutralization network is configured to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

Another exemplary embodiment includes a system which comprises a quantum processor comprising at least one superconducting quantum bit, and an arbitrary waveform generator comprising at least one arbitrary waveform generator channel configured to convert a baseband signal to a radio frequency control pulse which controls the at least one superconducting quantum bit. The at least one arbitrary waveform generator channel comprises a digital-to-analog converter circuit, a differential voltage-mode filter circuit, and a current-mode radio frequency output circuit. The digital-to-analog converter circuit comprises an output interface that is configured to generate a differential baseband voltage signal comprising a first baseband voltage signal and a second baseband voltage signal, which are complementary baseband voltage signals. The differential voltage-mode filter circuit is configured to filter the differential baseband voltage signal and output a filtered differential baseband voltage signal comprising a first filtered baseband voltage signal and a second filtered baseband voltage signal, which are complementary filtered baseband voltage signals. The current-mode radio frequency output circuit is coupled to the differential voltage-mode filter circuit, and is configured to convert the first filtered baseband voltage signal and the second filtered baseband voltage signal into a first baseband current signal and a second baseband current signal, respectively, for processing by the current-mode radio frequency output circuit to generate the radio frequency control pulse. The differential voltage-mode filter circuit comprises a first voltage-mode filter circuit that is configured to filter the first baseband voltage signal, a second voltage-mode filter circuit configured to filter the second baseband voltage signal, and a neutralization network comprising a first neutralization impedance circuit and a second neutralization impedance circuit. The first voltage-mode filter circuit and the second voltage-mode filter circuit each comprise a unity gain buffer having a nonzero output impedance. The first neutralization impedance circuit couples an input node of the first voltage-mode filter circuit to an output node of the second voltage-mode filter circuit, and the second neutralization impedance circuit couples an input node of the second voltage-mode filter circuit to an output node of the first voltage-mode filter circuit. The neutralization network is configured to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

Another exemplary embodiment includes a method which comprises: applying a differential voltage signal to a first input node and a second input node of a differential voltage-mode filter circuit to generate a filtered differential signal on a first output node and a second output node of the differential voltage-mode filter circuit, wherein the differential voltage-mode filter circuit comprises a first voltage-mode filter circuit and a second voltage-mode filter circuit each comprising a unity gain buffer having a nonzero output impedance, and a neutralization network comprising a first neutralization impedance circuit which couples an input node of the first voltage-mode filter circuit to an output node of the second voltage-mode filter circuit, and a second neutralization impedance circuit which couples an input node of the second voltage-mode filter circuit to an output node of the first voltage-mode filter circuit; and configuring the neutralization network to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

In another exemplary embodiment, as may be combined with the preceding paragraphs, the first neutralization impedance circuit and the second neutralization impedance circuit each comprise passive impedance elements. Advantageously, the use of passive impedance elements to implement the neutralizing network allows for an improved frequency response of the voltage-mode filter circuits using additional components that do not require DC biasing and thus, do not introduce any additional static power dissipation.

In another exemplary embodiment, as may be combined with the preceding paragraphs, the first neutralization impedance circuit comprises at least a first resistor and a first capacitor serially connected between the input node of the first voltage-mode filter circuit and the output node of the second voltage-mode filter circuit, and the second neutralization impedance circuit comprises at least a second resistor and a second capacitor serially connected between the input node of the second voltage-mode filter circuit and the output node of the first voltage-mode filter circuit. Advantageously, the use of resistors and capacitors to implement the first and second neutralization impedance circuits allows for an improved frequency response of the voltage-mode filter circuits using additional components that do not require DC biasing and thus, do not introduce any additional static power dissipation. In addition, the capacitors of the first and second neutralization impedance circuits allow the neutralization network to be completely decoupled from the DC biasing of the first and second voltage-mode filter circuits. As such, the neutralization network does not affect the differential voltage-mode filter circuit in terms of DC current biasing. DC power consumption, and common-mode voltage levels—the DC biasing conditions are invariant.

In another exemplary embodiment, as may be combined with the preceding paragraphs, the first capacitor and the second capacitor of the neutralization network are variable capacitors. Advantageously, the use of variable capacitors allows the capacitances of the neutralization network to be digitally controlled to tune the frequency response of the differential voltage-mode low-pass filter, and enables compensation for process and temperature variations.

Other embodiments will be described in the following detailed description of exemplary embodiments, which is to be read in conjunction with the accompanying figures.

### BRIEF DESCRIPTION OF THE DRAWINGS

FIG. 1 schematically illustrates a radio frequency signal generator system, according to an exemplary embodiment of the disclosure.

FIG. 2 schematically illustrates a radio frequency signal generator system which implements voltage-mode filter circuitry, according to another exemplary embodiment of the disclosure.

FIG. 3 schematically illustrates a voltage-mode filter circuit, according to an exemplary embodiment of the disclosure.

FIG. 4A schematically illustrates a differential voltage-mode filter circuit which comprises an output impedance neutralization network, according to an exemplary embodiment of the disclosure.

FIG. 4B schematically illustrates a differential voltage-mode filter circuit which comprises an output impedance neutralization network, according to another exemplary embodiment of the disclosure.

FIG. 5 graphically illustrates simulated responses of voltage-mode low-pass filters with and without output impedance neutralization, according to an exemplary embodiment of the disclosure.

FIGS. 6A, 6B, 6C, and 6D schematically illustrate a radio frequency signal generator system, according to another exemplary embodiment of the disclosure.

FIG. 7 schematically illustrates a gain control system which is implemented at an interface between a digital-to-analog converter circuit and a voltage-mode filter circuit of an RF signal generator system, according to an exemplary embodiment of the disclosure.

FIG. 8 schematically illustrates a quantum computing system which implements an arbitrary waveform generator system with voltage-mode filter circuitry, according to an exemplary embodiment of the disclosure.

FIG. 9 schematically illustrates a quantum computing system, according to another exemplary embodiment of the disclosure.

FIG. 10 schematically illustrates an exemplary computing environment which is configured to execute program instructions for performing quantum computing operations and calibration operations of a calibration system, according to an exemplary embodiment of the disclosure.

### DETAILED DESCRIPTION

Exemplary embodiments of the disclosure will now be described in further detail with regard to voltage-mode filter circuit architectures for use with RF signal generator systems, such as arbitrary waveform generator systems. The exemplary voltage-mode filter circuits disclosed herein provide low-power filter architectures which can be utilized with reduced supply voltage levels for low power consumption of RF signal generators such as AWG systems. In addition, the exemplary voltage-mode filter circuits as disclosed herein implement passive neutralization networks that are configured to neutralize a nonzero output impedance of output buffer stages of the voltage-mode filters and thereby enhance the filter frequency response, e.g., provide increased out-of-band rejection. It is to be noted that the phrases “neutralizing an output impedance” or “output impedance neutralization” or “neutralization network” are meant to broadly refer to a circuit or technique for cancelling or mitigating the negative effects on frequency response of a voltage-mode filter circuit as a result of the voltage-mode filter implementing a unity gain buffer output stage with a nonzero output impedance. For illustrative purposes, exemplary embodiments of the disclosure will be discussed in the context of output impedance neutralization techniques for Sallen-Key filters that are based on unity gain buffers, wherein a nonzero output impedance of the unity gain buffers (e.g., active source follower buffers) can adversely affect the frequency response of such filters. It is to be understood, however, that the exemplary techniques as discussed herein can be implemented with other types of voltage-mode filters which implement a unity gain output buffer as a key gain stage in which a nonzero output impedance of the unity gain buffer has a negative effect on the frequency response of the voltage-mode filter.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), superconducting elements such as superconducting quantum bits, programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

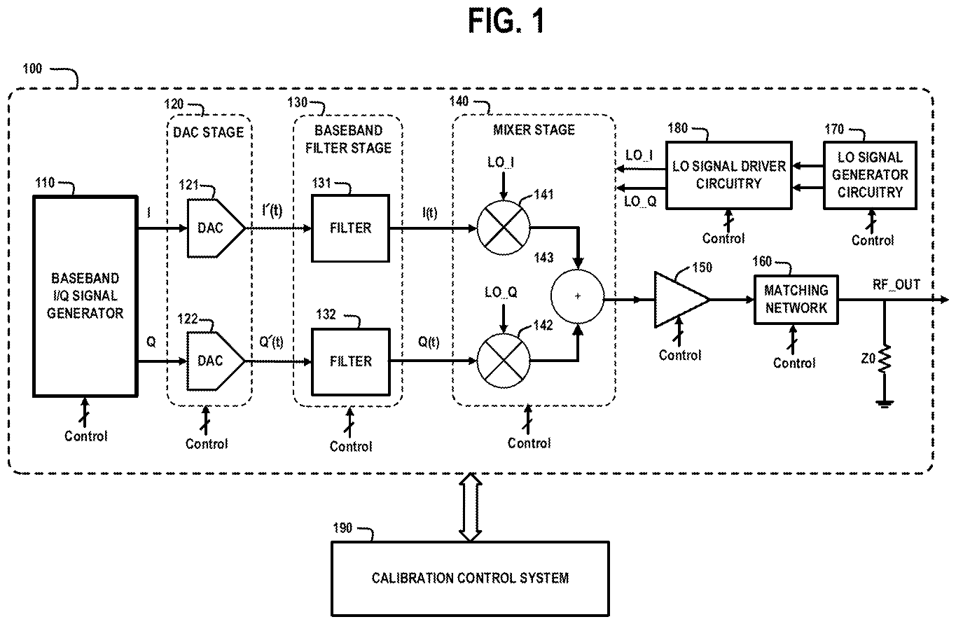

FIG. 1 schematically illustrates a radio frequency signal generator system, according to an exemplary embodiment of the disclosure. In particular, FIG. 1 schematically illustrates an RF signal generator system 100 which comprises a baseband I/Q signal generator 110, a digital-to-analog converter stage 120 (or DAC stage 120), a baseband filter stage 130, a mixer stage 140, an amplifier stage 150, an impedance matching network 160, local oscillator (LO) signal generator circuitry 170, and LO signal driver circuitry 180, the functions of which will be explained in further detail below. A calibration control system 190 is configured to calibrate various stages of the RF signal generator system 100 using digital control signals. The calibration control system 190 is implemented using a combination of software (e.g., program execution) and hardware (e.g., control logic and circuitry) to implement various control functions, as described herein.

As schematically illustrated in FIG. 1, the DAC stage 120 comprises inputs that are coupled to outputs of the baseband I/Q signal generator 110. The baseband filter stage 130 comprises inputs that are coupled to outputs of the DAC stage 120. The mixer stage 140 comprises inputs that are coupled to the outputs of the baseband filter stage 130. The amplifier stage 150 comprises inputs that are coupled to the outputs of the mixer stage 140, and an output that is coupled to an input of the impedance matching network 160, and an output of the impedance matching network 160 is coupled to an output node (RF_OUT) of the RF signal generator system 100. The LO signal generator circuitry 170 is configured to generate LO signals (e.g., quadrature LO signals) that are utilized by the mixer stage 140 to perform upconversion of the baseband signals. The LO signal driver circuitry 180 is configured to control the input of the LO signals to the mixer stage 140 for different modes of operation of the RF signal generator system 100 (e.g., real-time operating mode, and calibration mode), as will be discussed in further detail below.

It is to be understood that the RF signal generator system 100 can be implemented for various applications. For example, in some embodiments, the RF signal generator system 100 comprises an RF transmitter for a wireless application, wherein an output of the RF signal generator system 100 is coupled to an antenna system which is configured to transmit an RF output signal that is generated by the RF signal generator system 100. In other embodiments, the RF signal generator system 100 comprises a waveform generator (e.g., an AWG, or a function generator) in which the output of the RF signal generator system 100 is coupled to an input of a sensor device, wherein the RF output signal that is generated by the RF signal generator system 100 is configured to excite the sensor device. In other embodiments, for quantum computing applications, the RF signal generator system 100 comprises an AWG system which is configured to generate an RF control pulse for controlling the operation of, e.g., a superconducting qubit, an active superconducting coupler circuit which couples two superconducting qubits, or other superconducting quantum devices, etc.

In the context of the exemplary embodiments discussed herein, an RF signal comprises a signal which has a frequency ranging from, e.g., about 20 kHz to about 300 GHZ. In some embodiments, the RF signal generator system 100 comprises an analog quadrature system that is configured to generate quadrature (I/Q) signals (e.g., baseband I/Q signals and LO I/Q signals) and perform quadrature modulation (or I/Q signal modulation) to generate RF signals for a given application. As is known in the art, a quadrature signal comprises an in-phase (I) signal component, and a quadrature-phase (Q) signal component. A pair of signals that are in quadrature have the same frequency, but differ in phase by 90 degrees. For example, by convention, the I signal is a cosine waveform, and the Q signal is a sine waveform. For illustrative purposes, exemplary embodiments of the disclosure will be described in the context of quadrature RF signal generator systems, although the exemplary signal processing circuitry and methods as discussed herein can be implemented with other types of RF signal generator systems and modulation techniques.

In the exemplary embodiment of FIG. 1, the baseband I/Q signal generator 110 is configured to generate digital quadrature signals I and Q which represent input baseband data for a given application. For example, for quantum computing applications, the baseband I/Q signal generator 110 is configured to implement pulse-shaping techniques to generate RF control pulses with desired envelope shapes (e.g., Gaussian pulses, cosine pulses (e.g., sum of half cosines), hyperbolic secant pulses, etc.), which are applied to superconducting qubits or active qubit coupler circuits to perform single qubit gate operations, entanglement gate operations, etc. In some embodiments, the baseband I/Q signal generator 110 implements digital signal processing techniques based on a combination of hardware and software to generate the digital quadrature baseband signals I and Q.

The DAC stage 120 is configured to convert the digital quadrature signals I and Q to analog baseband signals I′(t) and Q′(t) having a target baseband frequency. In particular, the DAC stage 120 comprises multi-bit DAC circuits including a first DAC circuit 121 and a second DAC circuit 122. The first DAC circuit 121 is configured to convert the digital baseband component I to an analog baseband component I′(t) having a baseband frequency, and the second DAC circuit 122 is configured to convert the digital baseband component Q to an analog baseband component Q′(t) having the same baseband frequency, but phase-shifted by 90 degrees relative to I′(t). The DAC stage 120 generates and outputs the analog baseband signals I′(t) and Q′(t) at a given sampling rate (f_{S}) or sampling frequency, e.g., baseband frequencies in a range of about 100 kHz to about 1 GHz depending on the given application. In some embodiments, the first and second DAC circuits 121 and 122 implement a configurable hardware framework in which various operating parameters of the DAC stage 120 can be adjusted by digital control signals that are input to the DAC stage 120. For example, in some embodiments, the digital control can be utilized to adjust DAC operating parameters including, but not limited to, the sampling rate, analog full-scale output, etc.

Based on the Nyquist Sampling Theorem, the highest fundamental output frequency f_{O} signal a DAC with sampling frequency f_{S} can generate is equal to half the sampling rate or fₛ/2 (referred to as the first Nyquist zone). In the frequency domain, when generating a sinusoidal waveform of frequency f_{O}, the fundamental baseband frequency f_{O} will appear as a spectral component at f_{O}, and there will be additional higher frequency components that are generated at the output of the DAC stage 120, which are referred to as “images” and which are a function of f_{S} and f_{O}. For example, the higher frequency components are determined as |(n×f_{S})±f_{O}|, where n=1, 2, 3, . . . . The images have the same information content as the fundamental spectral components, but at higher frequencies and at smaller amplitudes. The unwanted images are suppressed/rejected using, e.g., the baseband filter stage 130.

The baseband filter stage 130 is configured to filter the analog baseband signals I′(t) and Q′(t) output from the DAC stage 120 to thereby generate filtered analog baseband signals I(t) and Q(t). The baseband filter stage 130 comprises a first filter circuit 131 and a second filter circuit 132. The first filter circuit 131 is configured to filter the in-phase analog signal I′(t) output from the first DAC circuit 121, and the second filter circuit 132 is configured to filter the quadrature-phase analog signal Q′(t) output from the second DAC circuit 122. In some embodiments, the first and second filter circuits 131 and 132 comprise low-pass filters that are configured to pass the fundamental spectral components of the respective analog signals I′(t) and Q′(t), while suppressing the image components of the respective analog signals I′(t) and Q′(t). In other embodiments, the first and second filter circuits 131 and 132 can be configured as bandpass filters to pass a desired band of higher frequency image components of the respective analog signals I′(t) and Q′(t), while suppressing the fundamental spectral components and other image components of the respective analog signals I′(t) and Q′(t). In other embodiments, the first and second filter circuits 131 and 132 can be configured as high-pass filters, as may be desired for a given application.

In some embodiments, the baseband filter stage 130 comprises configurable filter circuits in which, e.g., the cutoff frequencies of the first and second filter circuits 131 and 132 can be adjusted, or where the first and second filter circuits 131 and 132 can be configured to have different filter types (e.g., low-pass, band-pass, etc.) as desired for a given application. For example, in some embodiments, a bandpass filter can be configured using two low pass filters using known signal filtering techniques and architectures. In some embodiments, the filter configurations are digitally controlled by the digital control signals that are input to the baseband filter stage 130.

For example, a higher DAC sampling frequency can be utilized as needed to transmit baseband data and/or relax the filter response of the downstream filters of the baseband filter stage 130. Indeed, an increase in the DAC sampling frequency results in the possibility of accommodating higher baseband transmission frequency (i.e., the analog signals I′(t) and Q′(t) have a higher baseband frequency). In addition, an increase in the DAC sampling frequency results in an increase in the separation between the center frequency f_{O} of the baseband component and the center frequencies n×f_{S}±f_{O} of the higher frequency images, which relaxes the required sharpness of the filter cutoffs at corner frequencies of the filters. However, the higher DAC sampling rate results in increased power consumption. So, a tradeoff in power consumption with DAC sampling frequency, and the sharpness of the filter cutoffs at the corner frequencies of the filters are factors that should be considered.

In some embodiments, the mixer stage 140 is configured to perform analog I/Q signal modulation, e.g., single-sideband (SSB) modulation, by mixing the filtered analog signals I(t) and Q(t), which are output from the baseband filter stage 130, with quadrature LO signals (e.g., an in-phase LO signal (LO_I) and a quadrature-phase LO signal (LO_Q)) to generate and output an analog RF signal (e.g., a single-sideband modulated RF output signal). The local oscillator signals LO_I and LO_Q each have the same LO frequency, but the LO_Q signal is phase-shifted by 90 degrees relative to the LO_I signal. For amplitude modulation, the filtered analog signals I(t) and Q(t) amplitude modulate the LO_I and LO_Q signals.

More specifically, the mixer stage 140 comprises a first mixer circuit 141 (e.g., I mixer circuit), a second mixer circuit 142 (e.g., Q mixer circuit), and a signal combiner circuit 143. The first mixer circuit 141 is configured to mix the filtered analog signal I(t) with the LO_I signal and generate a first RF signal output. The second mixer circuit 142 is configured to mix the filtered analog signal Q(t) with the LO_Q signal and generate a second RF signal output. The first and second RF signals output from the first and second mixer circuits 141 and 142 are input to the signal combiner circuit 143 and combined (e.g., added) to generate a single-sideband RF signal output.

In some embodiments, a quadrature phase shifter circuit is implemented to generate the quadrature LO signals LO_I and LO_Q. For example, a quadrature phase shifter circuit is configured to receive an LO signal as input, and output the quadrature LO signals LO_I and LO_Q based on the LO input signal. In this configuration, the LO_I signal comprises the same frequency and phase as the input LO signal, and the LO_Q signal comprises the same frequency as the input LO signal, but with a phase shift of 90 degrees. The quadrature phase shifter circuit can be implemented using one of various quadrature phase shifting techniques known to those of ordinary skill in the art.

The mixer stage 140 performs an upconversion mixing process which is configured to generate an RF analog signal which has a center frequency that is greater than the baseband frequency of the baseband signals output from the DAC stage 120. In some embodiments, the LO frequency of the mixer stage 140 is in a range of 100 MHz to about 10 GHZ, depending on the application. More specifically, as is understood by those of ordinary skill in the art, as a result of the mixing operations of the first and second mixer circuits 141 and 142, the first and second RF signals that are output from the respective first and second mixer circuits 141 and 142 each comprise a double-sideband RF signal. A double-sideband signal comprises an upper sideband (USB) and a lower sideband (LSB) which are disposed at equal distances above and below the LO frequency. The upper sideband comprises a spectral band of frequencies that is higher than the LO frequency, and the lower sideband comprises a spectral band of frequencies that is lower than the LO frequency. The upper and lower sidebands each carry the same information content of the I/Q signals. For example, assume that the filtered analog signals I(t) and Q(t) (i.e., the modulating signals) have a center frequency f_{M} (intermediate frequency) and that the LO signal has a frequency f_{LO}. The first and second RF signals that are output from the first and second mixer circuits 141 and 142 will each have (i) an upper sideband of spectral components, which is frequency-band centered at a frequency of (f_{LO}+f_{M}) and (ii) a lower sideband of spectral components, which is frequency-band centered at a frequency of (f_{LO}−f_{M}).

In some embodiments, the signal combiner circuit 143 is configured to add the first and second RF signals which are output from the first and second mixer circuits 141 and 142, in which case the signal combiner circuit 143 will output the “real” lower sideband signal as a single-sideband modulated RF signal (with a suppressed carrier frequency) having a center frequency which is upconverted from the frequency f_{M} of the modulating signals I(t) and Q(t) to a center frequency (f_{LO}−f_{M}) of the lower sideband. In other embodiments, the signal combiner circuit 143 is configured to subtract the first and second RF signals which are output from the first and second mixer circuits 141 and 142, in which case the signal combiner circuit 143 will output the “real” upper sideband signal as a single-sideband modulated RF signal (with a suppressed carrier) having a center frequency which is upconverted from the frequency f_{M} of the modulating signals I(t) and Q(t) to a center frequency (f_{LO}+f_{M}) of the upper sideband. In other embodiments, the mixer stage 140 is configured as a double-sideband modulator (with a suppressed carrier frequency). More specifically, the mixer stage 140 can be configured to provide double-sideband modulation by maintaining the LO_Q input to the second mixer 142 at a constant zero voltage level (i.e., LO_Q=0). In this instance, the second mixer circuit 142 will have a zero output (i.e., no RF signal is output from the second mixer circuit 142), and the output of the signal combiner circuit 143 will be the double-sideband RF signal output from the first mixer circuit 141.

The amplifier stage 150 is configured to receive the modulated RF signal, which is output from the mixer stage 140, and amplify or attenuate the modulated RF signal to a desired power level, and drive the output of the RF signal generator system 100 (e.g., drive an antenna, sensor device, qubit, etc., which is coupled to the output of the RF signal generator system 100). In some embodiments, the amplifier stage 150 comprises a programmable gain, wherein gain can be expressed as a difference between the input power level (at the input to the amplifier stage 150) and the output power level (at the output of the amplifier stage 150) or, more specifically, as a ratio of output to input power. In some embodiments, the amplifier stage 150 is utilized to increase the power level of the RF output signal to a level which is sufficient to transmit (wirelessly or wired) the modulated RF signal at a given power level and over a required transmission distance. In other embodiments, the amplifier stage 150 comprises a programmable gain attenuation stage. The programmable gain attenuation stage comprises a programmable amplifier (or attenuator) which is configured to amplify a modulated RF signal with a gain factor of 1, or less than 1. In this manner, the programmable gain attenuation stage can attenuate the power level of modulated RF signals that are output from the mixer stage 140, as desired, for a given application.

The impedance matching network 160 is configured to match a source impedance or load impedance of the output of the amplifier stage 150 to a characteristic impedance of an output load (e.g., antenna input, diplexer, etc.) of the RF signal generator system 100. In some embodiments, the impedance matching network 160 comprises a balun to convert a differential/balanced output of the amplifier stage 150 to a single-ended/unbalanced output. In some embodiments, the parameters of the impedance matching network 160 (e.g., impedance at resonance and bandwidth) remain substantially invariant, wherein the impedance matching network 160 is designed with a center frequency which corresponds to a desired operating frequency of the load. In other embodiments, the impedance matching network 160 is configured with a plurality of injection points to provide different impedance matching and filtering characteristics. The different injection points can be selected by digital control signals applied to the impedance matching network 160. The impedance matching network 160 can have high pass and low pass characteristics, wherein the different injection points can be selected to provide different impedance matching and response characteristics. In some embodiments, the impedance matching network 160 is designed with a high-Q factor, wherein the center frequency of the impedance matching network 160 can be adjusted to provide a desired impedance transformation for different transmission frequencies which are generated by, e.g., changing the sampling frequency of the DAC stage 120 and/or changing the LO frequency of the mixer stage 140, depending on the given application.

In some embodiments, the LO signal generator circuitry 170 is configured to generate quadrature LO signals LO_I and LO_Q with a target center frequency, which are utilized by the mixer stage 140 to perform I/Q modulation and upconversion. In some embodiments, for a differential signal framework, the LO signal generator circuitry 170 is configured to generate complementary quadrature LO signals, which include complementary in-phase LO signals, LO_I and L̅O̅_̅I̅, and complementary quadrature-phase LO signals, LO_Q and L̅O̅_̅Q̅. Ideally, the complementary quadrature LO signals LO_I, LO_Q, L̅O̅_̅I̅, and L̅O̅_̅Q̅ have the same amplitude and center frequency, but different phases of 0°, 90°, 180°, and 270°, respectively.

The LO signal generator circuitry 170 can be implemented using known circuit architectures and LO signal generation techniques. For example, in some embodiments, the LO signal generator circuitry 170 comprises a phase-locked loop (PLL) system which is configured to generate an LO signal with a target center frequency, and phase-shifter circuitry which converts the LO signal generated by the PLL system, into quadrature LO signals LO_I and LO_Q. For differential quadrature LO signals, in some embodiments, the LO signal generator circuitry 170 can implement a quadrature phase-shifter circuit which is configured to receive as input a complementary pair of LO signals, LO and L̅O̅, and generate the complementary quadrature LO signals LO_I, LO_Q, L̅O̅_̅I̅, and LO_Q. In some embodiments, the quadrature phase-shifter circuit can be implemented using a quadrature polyphase phase-shifter circuit having a single polyphase filter stage, or multiple polyphase filter stages, as is known to those of ordinary skill in the art. The LO signal driver circuitry 180 comprises LO signal driver stages (e.g., CMOS buffers) which are configured to drive the LO inputs of the first and second mixer circuits 141 and 142 in the mixer stage 140 with the quadrature LO signals that are generated and output from the LO signal generator circuitry 170.

As shown in FIG. 1, the various signal processing stages 110, 120, 130, 140, 150, 160, 170, and 180 of the RF signal generator system 100 comprise control signal input ports that receive digital control signals from either the calibration control system 190 or some processor or microcontroller which is configured to control operation of the RF signal generator system 100. The calibration control system 190 is configured to generate digital control signals to configure the RF signal generator system 100, or signal processing stages thereof, to operate in different modes. Further, in some embodiments, some or all of the stages 110, 120, 130, 140, 150, 160, 170, and 180 have a configurable hardware framework in which various operating parameters and/or components of the stages can be adjusted by the digital control signals for different operating modes of the RF signal generator system 100.

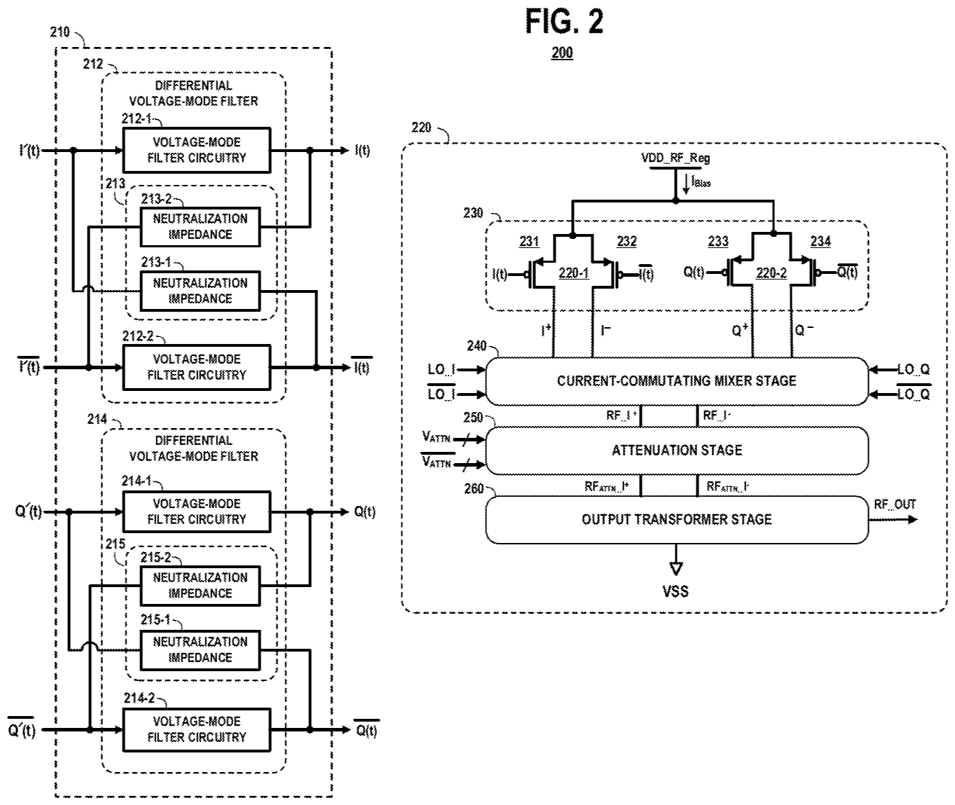

FIG. 2 schematically illustrates an RF signal generator system, according to another exemplary embodiment of the disclosure. More specifically, FIG. 2 schematically illustrates a radio frequency signal generator system 200 which implements voltage-mode filter circuitry, according to an exemplary embodiment of the disclosure. As shown in FIG. 2, the RF signal generator system 200 comprises a voltage-mode filter stage 210 and a current-mode RF output stage 220 of the RF signal generator system 200, according to an exemplary embodiment of the disclosure. The current-mode RF output stage 220 comprises a baseband signal stage 230, a current-commutating mixer stage 240, a signal attenuation stage 250, and an output transformer stage 260. In some embodiments, the RF signal generator system 200 is configured to operate with complementary in-phase baseband signals I(t) and I̅(̅t̅)̅, complementary quadrature-phase baseband signals Q(t) and Q̅(̅t̅)̅, and complementary quadrature LO signals comprising complementary in-phase LO signals LO_I and L̅O̅_̅I̅, and complementary quadrature-phase LO signals LO_Q and L̅O̅_̅Q̅.

The voltage-mode filter stage 210 comprises a first differential voltage-mode filter 212, and a second differential voltage-mode filter 214. The first differential voltage-mode filter 212 comprises a first voltage-mode filter circuit 212-1, a second voltage-mode filter circuit 212-2, and a neutralization network 213 which comprises a first neutralization impedance circuit 213-1 and a second neutralization impedance circuit 213-2. The second differential voltage-mode filter 214 comprises a first voltage-mode filter circuit 214-1, a second voltage-mode filter circuit 214-2, and a neutralization network 215 which comprises a first neutralization impedance circuit 215-1 and a second neutralization impedance circuit 215-2. In some embodiments, the neutralization impedance circuits 213-1, 213-2, 215-1, and 215-2 comprise passive impedance components such as resistors and capacitors, which can be fixed or variable.

In some embodiments, the first differential voltage-mode filter 212 comprises a differential analog low-pass filter, wherein the first voltage-mode filter circuit 212-1 and the second voltage-mode filter circuit 212-2 are configured to receive and filter respective complementary in-phase baseband signals I′(t) and I̅′̅(̅t̅)̅, and output filtered complementary in-phase baseband signals I(t) and I̅(̅t̅)̅. Similarly, in some embodiments, the second differential voltage-mode filter 214 comprises a differential analog low-pass filter, wherein the first voltage-mode filter circuit 214-1 and the second voltage-mode filter circuit 214-2 are configured to receive and filter respective complementary quadrature-phase baseband signals Q′(t) and Q̅′̅(̅t̅)̅, and output filtered complementary quadrature-phase baseband signals Q(t) and Q̅(̅t̅)̅.

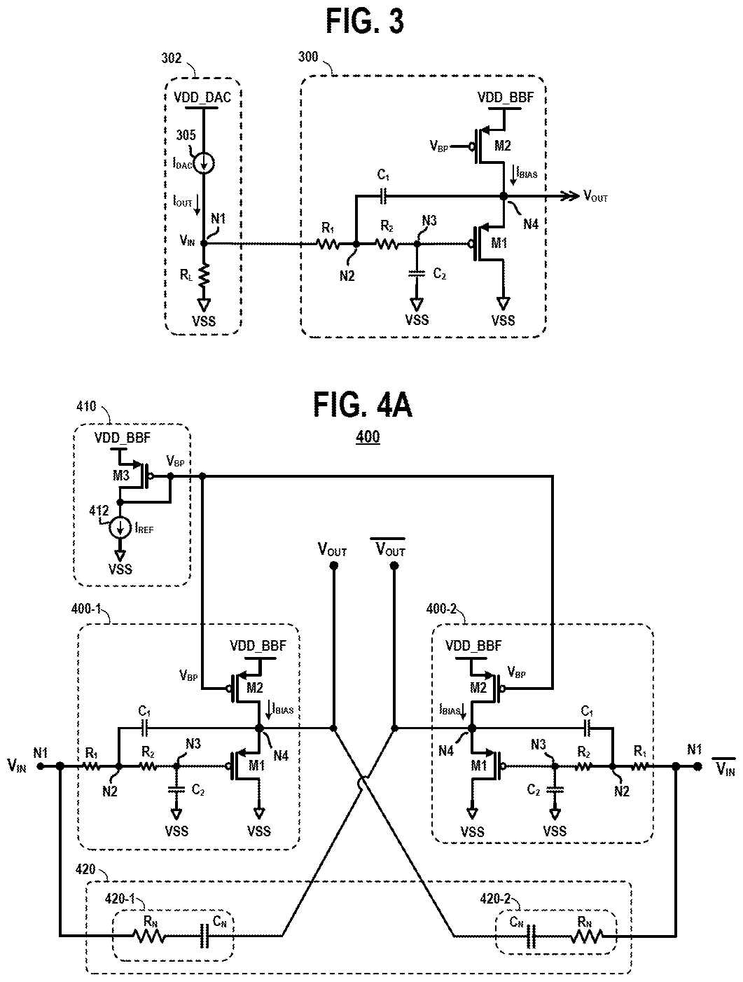

In some embodiments, the voltage-mode filter circuits 212-1, 212-2, 214-1, and 214-2 each comprise an analog biquadratic low-pass filter circuit which utilizes a unity gain source follower circuit. For example, in some embodiments, the voltage-mode filter circuits 212-1, 212-2, 214-1, and 214-2 each employ a single-transistor Sallen-Key filter architecture (an exemplary embodiment of which will be described in further detail below in conjunction with FIG. 3). Such implementations of analog biquadratic low-pass filter circuits have transfer functions with zeros that result from a nonzero output impedance of the low-pass filter circuits (whose output impedance is limited by the output impedance of the unity gain source follower circuits). The neutralization networks 213 and 215 comprise output impedance neutralization networks that are configured to neutralize the nonzero output impedances of the voltage-mode filter circuits 212-1, 212-2, 214-1, and 214-2 and thereby enhance the out-of-band rejection response of such filters. The neutralization networks 213 and 215 are configured to effectively cancel the transfer-function zeros (or transmission zeros) resulting from the nonzero output impedances of the voltage-mode filter circuits 212-1, 212-2, 214-1, and 214-2.

More specifically, the neutralization network 213 is configured to cancel the transfer-function zeros (or transmission zeros) of the first and second voltage-mode filter circuits 212-1 and 212-2 of the first differential voltage-mode filter 212, which result from the nonzero output impedances of the first and second voltage-mode filter circuits 212-1 and 212-2. In some embodiments, as schematically illustrated in FIG. 2, such neutralization is achieved by (i) coupling the input of the first voltage-mode filter circuit 212-1 to the output of the second voltage-mode filter circuit 212-2 through the first neutralization impedance circuit 213-1 and (ii) coupling the input of the second voltage-mode filter circuit 212-2 to the output of the first voltage-mode filter circuit 212-1 through the second neutralization impedance circuit 213-2. In this exemplary configuration, the neutralization network 213 comprises cross-coupled neutralization impedance circuits 213-1 and 213-2.

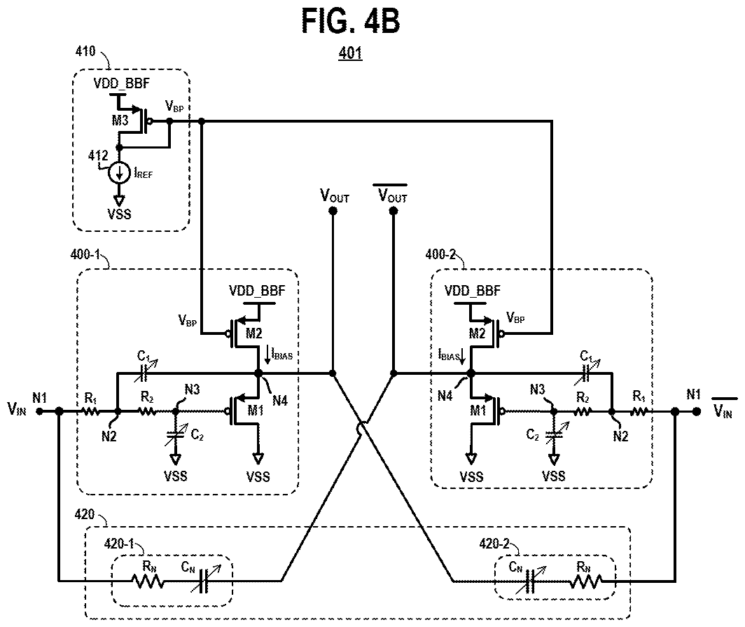

Similarly, the neutralization network 215 is configured to cancel the transfer-function zeros (or transmission zeros) of the first and second voltage-mode filter circuits 214-1 and 214-2 of the second differential voltage-mode filter 214, which result from the nonzero output impedances of the first and second voltage-mode filter circuits 214-1 and 214-2. In some embodiments, as schematically illustrated in FIG. 2, such neutralization is achieved by (i) coupling the input of the first voltage-mode filter circuit 214-1 to the output of the second voltage-mode filter circuit 214-2 through the first neutralization impedance circuit 215-1 and (ii) coupling the input of the second voltage-mode filter circuit 214-2 to the output of the first voltage-mode filter circuit 214-1 through the second neutralization impedance circuit 215-2. In this exemplary configuration, the neutralization network 215 comprises cross-coupled neutralization impedance circuits 215-1 and 215-2. Exemplary embodiments of the voltage-mode filter stage 210 and the associated first and second differential voltage-mode filters 212 and 214 will be discussed in further detail below in conjunction with the exemplary voltage-mode filter circuit architectures shown in, e.g., FIGS. 3, 4A and 4B.

In some embodiments, the current-mode RF output stage 220 comprises a current-mode architecture in which the signal processing is performed using time-varying current signals that are generated by the baseband signal stage 230 and injected into I/Q signal paths (I⁺, I⁻, Q⁺, and Q⁻) to perform I/Q modulation and upconversion. The baseband signal stage 230 is configured to convert the complementary in-phase voltage baseband signals I(t) and I̅(̅t̅)̅ and complementary quadrature-phase baseband voltage signals Q(t) and Q̅(̅t̅)̅, which are output from the respective first and second differential voltage-mode filters 212 and 214, into time varying analog I/Q current signals that are applied to the I/Q signal paths I⁺, I⁻, Q⁺, and Q⁻. More specifically, as schematically illustrated in FIG. 2, the baseband signal stage 230 comprises a plurality of baseband transistors 231, 232, 233, and 234 which, in some embodiments, are p-type metal-oxide-semiconductor (PMOS) transistors. The baseband transistors 231 and 232 comprise a first differential transistor pair 220-1, which have commonly connected source terminals coupled to a regulated voltage rail (denoted VDD_RF_Reg), and respective gate terminals which receive the complementary in-phase baseband voltage signals I(t) and I̅(̅t̅)̅, respectively, that are output from the respective first and second voltage-mode filter circuits 212-1 and 212-2 of the first differential voltage-mode filter 212.

Similarly, the baseband transistors 233 and 234 comprise a second differential transistor pair 220-2, which have commonly connected source terminals coupled to the regulated voltage rail (denoted VDD_RF_Reg), and respective gate terminals which receive the complementary quadrature-phase baseband voltage signals Q(t) and Q̅(̅t̅)̅, respectively, that are output from the respective first and second voltage-mode filter circuits 214-1 and 214-2 of the second differential voltage-mode filter 214. The baseband transistors 231, 232, 233, and 234 comprise respective drain terminals that inject I/Q current signals from the baseband signal stage 230 into the respective I/Q signal paths I+, I−, Q+, and Q. The baseband transistors 231, 232, 233, and 234 are biased at a level of static bias current I_{Bias} which flows from the regulated voltage rail VDD_RF_Reg, and which is distributed to the source terminals of the baseband transistors 231, 232, 233, and 234.

The current-commutating mixer stage 240 is configured to perform analog I/Q modulation and upconversion from baseband to RF frequencies. As shown in FIG. 2, the current-commutating mixer stage 240 is configured to receive complementary in-phase LO signals LO_I and L̅O̅_̅I̅ and complementary quadrature-phase LO signals LO_Q and L̅O̅_̅Q̅. In some embodiments, the current-commutating mixer stage 240 comprises a differential I mixer circuit and a differential Q mixer circuit. The differential I mixer circuit comprises LO inputs which receive the complementary in-phase LO signals LO_I and L̅O̅_̅I̅, and the differential Q mixer circuit comprises LO inputs which receive the complementary quadrature-phase LO signals LO_Q and L̅O̅_̅Q̅. The differential I and Q mixer circuits receive as input the analog I/Q current signals on the signal paths I⁺, I⁻, Q⁺, and Q⁻ and perform mixing/modulation operations to generate time-varying output current signals which are summed/subtracted to achieve the SSB I/Q modulation and generate an RF output signal, e.g., differential RF current signals RF_I⁺ and RF_I⁻.

The signal attenuation stage 250 is configured to adjust a signal strength of the differential RF current signals RF_I⁺ and RF_I⁻ based on a digital attenuation code specified by differential multi-bit attenuation control signals V_{ATTN} and V̅_̅{̅A̅T̅T̅N̅}̅. More specifically, in some embodiments, the signal attenuation stage 250 is configured to adjust the magnitudes of differential RF current signals RF_{ATTN}_I⁺ and RF_{ATTN}_I⁻ that flow to the output transformer stage 260. In some embodiments, the output transformer stage 260 comprises circuitry that is configured to convert a differential output signal into a single-ended output signal RF_OUT. The output transformer stage 260 can be implemented using various techniques and circuit configurations for transforming a differential output signal to a single-ended output signal, which are suitable for the given application and which are well known to those of ordinary skill in the art.

It is to be noted that in some embodiments, the RF signal generator system 200 illustrates an exemplary embodiment of the RF signal generator system 100 having a complementary quadrature architecture which is configured to operate with the complementary in-phase baseband signals I(t) and I̅(̅t̅)̅, the complementary quadrature-phase baseband signals Q(t) and Q̅(̅t̅)̅, and the complementary quadrature LO signals comprising the complementary in-phase LO signals LO_I and L̅O̅_̅I̅, and the complementary quadrature-phase LO signals LO_Q and L̅O̅_̅Q̅. In such embodiments, the voltage-mode filter stage 210 of FIG. 2 schematically illustrates an exemplary embodiment of the baseband filter stage 130 of FIG. 1. In addition, the baseband signal stage 230 and the current-commutating mixer stage 240 schematically illustrate an exemplary embodiment of the mixer stage 140 of FIG. 1. Further, the signal attenuation stage 250 schematically illustrates an exemplary embodiment of the amplifier stage 150 of FIG. 1. Moreover, in some embodiments, the output transformer stage 260 represents an exemplary embodiment of the impedance matching network 160 of FIG. 1. In some embodiments, the output transformer stage 260 comprises circuitry for transforming a differential output signal to a single-ended output signal. The output transformer stage 260 can be implemented using various techniques and circuit configurations for transforming a differential output signal to a single-ended output signal, which are suitable for the given application and which are well known to those of ordinary skill in the art.

FIG. 3 schematically illustrates a voltage-mode filter circuit, according to an exemplary embodiment of the disclosure. In particular, FIG. 3 schematically illustrates a voltage-mode filter circuit 300 which, in some embodiments, is utilized to implement each of the voltage-mode filter circuits 212-1, 212-2, 214-1, and 214-2 in FIG. 2. In addition, FIG. 3 schematically illustrates a DAC circuit 302 (e.g., current steering DAC circuit) which interfaces with the voltage-mode filter circuit 300. The voltage-mode filter circuit 300 comprises an input node N1, which receives as input an analog baseband input voltage signal V_{IN} which is generated by the DAC circuit 302.

The DAC circuit 302 comprises a current source 305 which generates a DAC current I_{DAC}, and a voltage-mode output interface which comprises a load resistor R_{L} that is connected between the node N1 and ground node VSS. It is to be understood that FIG. 3 provides a high-level schematic illustration of a current-steering DAC circuit having a current source architecture represented by the current source 305 which comprises a current source array (e.g., array of transistors) that is controlled by an n-bit digital signal (e.g., b1, b2, . . . , bn) where each bit causes the current source 305 to switch out a fixed amount of current to the node N1. The current output (I_{OUT}) from the current source 305 is converted to a voltage (V_{IN}) on the node N1 by the relationship V_{IN}=I_{OUT}·R_{L}. The current source 305 provides a digitally controlled DAC current level (denoted by I_{OUT}) which flows through the DAC load resistor R_{L} to generate an analog baseband input voltage signal V_{IN} at node N1. In an exemplary non-limiting embodiment, the resistor R_{L} has a relatively low resistance value (e.g., about 300 to 400 Ohms). In an exemplary non-limiting embodiment, the DAC voltage-mode interface is configured to generate an analog baseband input voltage signal V_{IN} having a DC common-mode voltage of about 80 millivolts (mV) and a peak-to-peak voltage (VPP) of about 160 mV. Assuming that the full-scale DAC current level is fixed, the amplitude of the voltage V_{IN} (e.g., maximum voltage swing V_{PP} and the common-mode (CM) voltage) on the node N1 will increase if a larger load resistor R_{L} is used.

The voltage-mode filter circuit 300 comprises an analog biquadratic low-pass filter framework which comprises a first transistor M1 (e.g., PMOS transistor), a first resistor R₁, a second resistor R₂, a first capacitor C₁, and a second capacitor C₂. The voltage-mode filter circuit 300 further comprises a second transistor M2 which serves as a bias transistor (i.e., a current source). The first resistor R₁ is coupled to the input node N1 and to a second node N2 (alternatively, feedback node N2). The second resistor R₂ is coupled to the second node N2 and to a third node N3. The first capacitor C₁ is coupled to the second node N2 and to a fourth node N4, which provides a feedback path (from node N4 to node N2) of the voltage-mode filter circuit 300. The second capacitor C₂ is coupled to the third node N3 and to the negative supply voltage node VSS. The first transistor M1 comprises a gate terminal which is coupled to the third node N3, a source terminal which is coupled to the fourth node N4 (i.e., coupled to the feedback path of the voltage-mode filter circuit 300), and a drain terminal which is coupled to the negative supply voltage node VSS.

As noted above, the second transistor M2 (e.g., mirror transistor) comprises a biasing element which is configured to generate a bias current I_{BIAS} for operating the voltage-mode filter circuit 300 at a given operating point. The second transistor M2 is a PMOS transistor which comprises a gate terminal that receives a bias voltage V_{BP}, a source terminal that is coupled to a positive power supply node VDD_BBF, and a drain terminal that is coupled to the fourth node N4. In some embodiments, the bias voltage V_{BP} comprises a DC voltage which is generated by a reference circuit of a current mirror circuit, and applied to the gate terminal of the second transistor M2. In some embodiments, the second transistor M2 is a mirror transistor in a current mirror circuit which generates the bias current I_{BIAS} in proportion (e.g., 1:1 ratio, or greater) to a reference current I_{REF} generated by the reference circuit of the current mirror circuit, as is understood by those of ordinary skill in the art (exemplary embodiments of which are shown in FIGS. 4A and 4B).

The voltage-mode filter circuit 300 comprises an analog biquadratic low-pass filter framework which is a variation of a low-pass 2^{nd} order (2 complex poles) Sallen-Key filter (or positive feedback filter). The Sallen-Key filter configuration in FIG. 3 is implemented using a single transistor, i.e., the first transistor M1, in a source follower configuration (providing a unity gain source follower buffer), instead of an operational amplifier as is typically implemented in conventional Sallen-Key filters and biquadratic low-pass filter designs. In the voltage-mode filter circuit 300, the filter feedback loop is implemented by coupling the source terminal of the first transistor M1 to the feedback node N2 through the first capacitor C₁.

As compared to conventional biquadratic low-pass filter circuits, the implementation of the Sallen-Key filter circuit architecture (as shown in FIG. 3) based on the single transistor (source follower) active stage provides lower power consumption, low distortion, and a smaller footprint (less occupied area). In addition, by using the voltage-mode filter circuit 300, an analog signal path can be implemented in an RF signal generator system with at least the baseband filter stages operating at relatively low supply voltage VDD_BBF (e.g., 500 mV to about 700 mV) for low power consumption.

In the exemplary embodiment of FIG. 3, a voltage output (V_{OUT}) of the voltage-mode filter circuit 300 is taken at the fourth node N4, which is the source terminal of the first transistor M1. In other words, the fourth node N4 is the output node of the active source follower stage of the voltage-mode filter circuit 300 stage. Ignoring next stage loading, and assuming (in an ideal case) that the active source follower stage has a zero (0) output impedance, the frequency response H(s) (i.e., s-domain transfer function) of the voltage-mode filter circuit 300 is expressed as:

$$H ( s ) = \frac{{{ω}_{o}}^{2}}{( {s}^{2} + 2 α s + {{ω}_{o}}^{2} )} ,$$

where ωₒ denotes a center frequency expressed as

$${ω}_{o} = \frac{1}{\sqrt{{R}_{1} {R}_{2} {C}_{1} {C}_{2}}} ,$$

$$where α = \frac{1}{2 {C}_{1}} ( \frac{1}{{R}_{1}} + \frac{1}{{R}_{2}} ) ,$$

and wherein the filter circuit 300 has a quality factor of

$$Q = \frac{{ω}_{o}}{2 α} .$$

In other terms, for a zero (0) output impedance, the frequency response H(s) of the voltage-mode filter circuit 300 is expressed as:

$$H ( s ) = \frac{1}{{s}^{2} \cdot {C}_{1} \cdot {C}_{2} \cdot {R}_{1} \cdot {R}_{2} + s \cdot {C}_{2} \cdot ( {R}_{1} + {R}_{2} ) + 1} ,$$

which represents an ideal response of a second order low-pass filter having two “poles” and no “zeros.”

On the other hand, the active source follower stage will have a nonzero output impedance at node N4, which introduces additional “zeros” in the transfer function of the voltage-mode filter circuit 300 and, as a result, degrades the low-pass response of the voltage-mode filter circuit 300. To reduce the output impedance, a larger size device for the transistor M1 can be used, and the bias current I_{BIAS} can be increased. In practice, a larger bias current may require increasing the device width of transistor M2 as well. In any event, an increase in the static bias current would increase the power dissipation of the voltage-mode filter circuit 300, which is undesirable. In addition, a larger size transistor device for M1 would result in an increased parasitic capacitance, which would limit the bandwidth of the voltage-mode filter circuit 300.

Therefore, to achieve low power operation, in a non-ideal case, the active source follower stage will have a nonzero output impedance which, as noted above, introduces additional “zeros” in the transfer function of the voltage-mode filter circuit 300, resulting in a degraded filter response. In particular, assuming the active source follower stage has an output impedance, denoted R_{OUT}, the voltage-mode filter circuit 300 will have a frequency response H(s) expressed as:

$$H ( s ) = \frac{( {s}^{2} \cdot {C}_{1} \cdot {C}_{2} \cdot {R}_{2} \cdot {R}_{OUT} ) + ( s \cdot {C}_{1} \cdot {R}_{OUT} ) + 1}{\begin{matrix}{s}^{2} \cdot {C}_{1} \cdot {C}_{2} \cdot ( {R}_{1} \cdot {R}_{2} + {R}_{1} \cdot {R}_{OUT} + {R}_{2} \cdot {R}_{OUT} ) + \\ s \cdot ( {C}_{2} \cdot {R}_{1} + {C}_{2} \cdot {R}_{2} + {C}_{1} \cdot {R}_{OUT} ) + 1\end{matrix}} ,$$

which has two “zeros” (roots of numerator) and two “poles” (roots of denominator). The filter “zeros” negatively impact the low-pass filter response at higher frequencies, resulting in poor out-of-band rejection. For example, the two zeros result in a flat frequency response at frequencies much greater than the corner (cutoff) frequency of the voltage-mode filter circuit 300, which is undesirable as such a response has poor out-of-band rejection.

In some embodiments, the voltage-mode filter circuit 300 can be modified to provide a better filter response by connecting an additional PMOS source follower buffer circuit to the gate terminal (node N3) of the first transistor M1, and taking the voltage output (VOLT) from the source node of the additional PMOS source follower buffer circuit. In this configuration, the common-mode voltage at the input node N1 of the voltage-mode filter circuit 300 is the same as the common-mode voltage at node N3, which would serve as the input node to the additional PMOS source follower buffer circuit. The additional buffer circuit would serve to buffer the output of the voltage-mode filter circuit 300, so that the output node would be isolated from the loading of the feedback capacitor C₁ and the rest of the feedback path. This extra isolation would improve the frequency response of the filter and enhance the out-of-band rejection. However, for low power applications, the additional PMOS buffer circuit would result in increased power dissipation due to the static bias current of the additional PMOS buffer circuit, which is undesirable. Furthermore, the additional PMOS buffer circuit would increase the footprint of the voltage-mode filter circuit 300, which may be undesirable.

As noted above, output impedance neutralization techniques are implemented to neutralize the nonzero output impedance of the voltage-mode filter circuit 300 and thereby enhance the low-pass filter frequency response of the voltage-mode filter circuit 300 and especially the out-of-band rejection. In some embodiments, a differential neutralization scheme using feedforward passive impedance branches is implemented to inject currents to the output nodes of a differential voltage-mode filter circuit from opposite polarities of input signals at the input nodes of the differential voltage-mode filter circuit to compensate (e.g., cancel) transmission zeros. For example, FIG. 4A schematically illustrates a differential voltage-mode filter circuit which comprises an output impedance neutralization network to enhance an out-of-band rejection filter response, according to an exemplary embodiment of the disclosure.

More specifically, FIG. 4A schematically illustrates a differential voltage-mode filter circuit 400 comprising a first voltage-mode filter circuit 400-1, a second voltage-mode filter circuit 400-2, a current reference circuit 410, and a neutralization network 420. The neutralization network 420 comprises a first neutralization impedance circuit 420-1 and a second neutralization impedance circuit 420-2 in a cross-coupled configuration. In some embodiments, the first voltage-mode filter circuit 400-1 and the second voltage-mode filter circuit 400-2 each have a same circuit architecture as the voltage-mode filter circuit 300 of FIG. 3, the details of which will not be repeated. The current reference circuit 410 comprises a transistor M3 and a constant current source 412 which generates a reference current I_{REF}. The current reference circuit 410 is configured to generate a static bias voltage V_{BP} which is commonly applied to the gate terminals of the second transistors M2 of the first and second voltage-mode filter circuits 400-1 and 400-2. In this configuration, the current reference circuit 410 and the second transistors M2 form a current mirror circuit, wherein the transistor M3 comprises a reference transistor and the second transistors M2 comprise mirror transistors of the current mirror circuit, and wherein the second transistors M2 each generate a bias current I_{BIAS} in proportion (e.g., 1:1 ratio, or greater) to the reference current I_{REF} of the current reference circuit 410.

FIG. 4A schematically illustrates an exemplary embodiment in which the differential voltage-mode filter circuit 400 comprises an analog differential biquadratic low-pass filter which (i) receives a differential voltage input signal comprising complementary input signals V_{IN} and V̅_̅{̅I̅N̅}̅ (where V_{IN} denotes the non-inverted input voltage and V̅_̅{̅I̅N̅}̅ denotes the inverted input voltage), and (ii) outputs a filtered differential voltage signal comprising complementary output signals V_{OUT} and V̅_̅{̅O̅U̅T̅}̅. In particular, as shown in FIG. 4A, the voltage input signal V_{IN} is applied to the input node N1 of the first voltage-mode filter circuit 400-1 and the filtered voltage output signal V_{OUT} is generated at the output node N4 of the first voltage-mode filter circuit 400-1. Further, the voltage input signal V̅_̅{̅I̅N̅}̅ is applied to the input node N1 of the second voltage-mode filter circuit 400-2 and the filtered voltage output signal V̅_̅{̅O̅U̅T̅}̅ is generated at the output node N4 of the second voltage-mode filter circuit 400-2.

Moreover, as schematically illustrated in FIG. 4A, the input node N1 of the first voltage-mode filter circuit 400-1 is coupled to the output node N4 of the second voltage-mode filter circuit 400-2 through the first neutralization impedance circuit 420-1. Similarly, the input node N1 of the second voltage-mode filter circuit 400-2 is coupled to the output node N4 of the first voltage-mode filter circuit 400-1 through the second neutralization impedance circuit 420-2. In some embodiments, the first and second neutralization impedance circuits 420-1 and 420-2 each comprise passive impedance elements including a resistor R_{N} and a capacitor C_{N}. The first and second neutralization impedance circuits 420-1 and 420-2 are each configured to inject current to an output node from an opposite polarity of the input signal using the passive impedance components to effectively cancel the effects of the nonzero output impedances of the first and second voltage-mode filter circuits 400-1 and 400-2. In this regard, the exemplary output impedance neutralization technique utilizes a differential signal architecture to neutralize the negative effects of the nonzero output impedances of the first and second voltage-mode filter circuits 400-1 and 400-2 on the low-pass filter responses of the first and second voltage-mode filter circuits 400-1 and 400-2.

In the exemplary embodiment of FIG. 4A, the neutralization network 420 can be configured to provide an improved low-pass filter frequency response by, e.g., providing a higher bandwidth and sharper frequency response with a high out-of-band attenuation/rejection. For example, assuming that the first voltage-mode filter circuit 400-1 and the second voltage-mode filter circuit 400-2 are essentially identical in circuit architecture and component values, and assuming that the transistors M1 each have an output impedance Rₒᵤₜ, the frequency response H(s) of each of the first voltage-mode filter circuit 400-1 and the second voltage-mode filter circuit 400-2 is expressed as:

$$H ( s ) = \frac{{V}_{out}}{{V}_{in}} = \frac{num}{den} , where :$$

$$num = {s}^{3} ( {C}_{1} {C}_{2} {C}_{N} {R}_{2} {R}_{out} {R}_{N} - {C}_{1} {C}_{2} {C}_{N} {R}_{1} {R}_{2} {R}_{out} ) + {s}^{2} ( \text{} {C}_{1} {C}_{2} {R}_{2} {R}_{out} - {C}_{1} {C}_{N} {R}_{1} {R}_{out} + {C}_{1} {C}_{N} {R}_{out} {R}_{N} - {C}_{2} {C}_{N} {R}_{1} {R}_{out} - {C}_{2} {C}_{N} {R}_{2} {R}_{out} ) + s ( {C}_{1} {R}_{out} - {C}_{N} {R}_{out} + {C}_{N} {R}_{N} ) + 1 ; and$$

$$den = {as}^{3} + {bs}^{2} + cs + 1 ,$$

$$where :$$

$$a = [ ( {C}_{1} {C}_{2} {C}_{N} {R}_{1} {R}_{2} {R}_{OUT} ) + ( {C}_{1} {C}_{2} {C}_{N} {R}_{1} {R}_{2} {R}_{N} ) + ( {C}_{1} {C}_{2} {C}_{N} {R}_{1} {R}_{OUT} {R}_{N} ) ] ;$$

$$b = [ ( {C}_{1} {C}_{2} {R}_{1} {R}_{2} ) + ( {C}_{1} {C}_{N} {R}_{1} {R}_{OUT} ) + ( {C}_{1} {C}_{2} {R}_{1} {R}_{OUT} ) + ( {C}_{2} {C}_{N} {R}_{1} {R}_{OUT} ) + ( {C}_{2} {C}_{N} {R}_{1} {R}_{N} ) + ( {C}_{1} {C}_{2} {R}_{2} {R}_{OUT} ) + ( {C}_{2} {C}_{N} {R}_{2} {R}_{OUT} ) + ( {C}_{2} {C}_{N} {R}_{2} {R}_{N} ) + ( {C}_{1} {C}_{N} {R}_{OUT} {R}_{N} ) ] ;$$

$$c = [ ( {C}_{2} {R}_{1} ) + ( {C}_{2} {R}_{2} ) + ( {C}_{1} {R}_{OUT} ) + ( {C}_{1} {R}_{OUT} ) + ( {C}_{N} {R}_{OUT} ) + ( {C}_{N} {R}_{N} ) ] .$$

The numerator, num, can be simplified by cancelling the s³ and s² terms by setting R_{N}=R₁ and setting

$${C}_{N} = ( \frac{{R}_{2}}{{R}_{1} + {R}_{2}} ) {C}_{1} .$$

With such terms cancelled, the frequency response H(s) of each of the first and second voltage-mode filter circuits 400-1 and 400-2 simplifies to:

$$H ( s ) = \frac{s ( {C}_{1} \cdot {R}_{OUT} - {C}_{N} \cdot {R}_{OUT} + {C}_{N} \cdot {R}_{N} ) + 1}{{as}^{3} + {bs}^{2} + cs + 1} ,$$

which is shown to have one “zero” and three “poles.” In other words, the above equations illustrate an exemplary embodiment in which the impedance values of R_{N} and Cy of the neutralization network 420 can be chosen to correct a frequency response of each of the first voltage-mode filter circuit 400-1 and the second voltage-mode filter circuit 400-2 by either cancelling, or otherwise compensating for, at least one transmission zero of a transfer function of each of the first voltage-mode filter circuit 400-1 and the second voltage-mode filter circuit 400-2, which results from the nonzero output impedance Rₒᵤₜ of the respective unity gain buffers (e.g., unity gain source follower buffers).

This is to be contrasted with the frequency response H(s) of the voltage-mode filter circuit 300 (FIG. 3) which, in the absence of an output impedance neutralization network, has two “zeros” and two “poles” as discussed above. In this regard, the output impedance neutralization network 420 mitigates the effects of the nonzero output impedance R_{OUT} of the active source follower stage (i.e., the output impedance at the source node N4 of the source follower transistors M1) and improves the filter frequency response.

FIG. 4B schematically illustrates a differential voltage-mode filter circuit which comprises an output impedance neutralization network, according to another exemplary embodiment of the disclosure. In particular, FIG. 4B schematically illustrates a differential voltage-mode filter circuit 401 which is similar to the differential voltage-mode filter circuit 400 of FIG. 4A, except that the capacitors C₁ and C₂ of the first and second voltage-mode filter circuits 400-1 and 400-2, and the capacitors C_{N} of the neutralization network 420 are implemented as variable capacitors, which can be digitally controlled. In this regard, the capacitance values of the variable capacitors C₁, C₂, and C_{N} can be digitally tuned to tune the frequency response of the differential voltage-mode low-pass filter, which enables compensation for process and temperature (PT) variations, etc.

It is to be noted that the exemplary output impedance neutralization networks and techniques as discussed herein can be configured to compensate for the negative effects of a nonzero output impedance of a unity gain buffer stage of a voltage-mode filter circuit (e.g., a unity gain source follower buffer stage of a Sallen-Key filter circuit) by adding one or more transmission poles to the filter transfer function, wherein such transmission poles do not exactly “cancel” transmission zeros, but rather are close enough that such the transmission poles effectively compensate the transmission zeros in a way that corrects or otherwise enhances the frequency response of the voltage-mode filter circuit, as discussed herein. It is to be further noted that while FIGS. 4A and 4B illustrate exemplary filter embodiments which implement one stage of a differential voltage-mode filter circuit 400 and 401, respectively, in other embodiments, multiple instances of the differential voltage-mode filter circuit 400 or the differential voltage-mode filter circuit 401 can be cascaded to form higher-order filters.

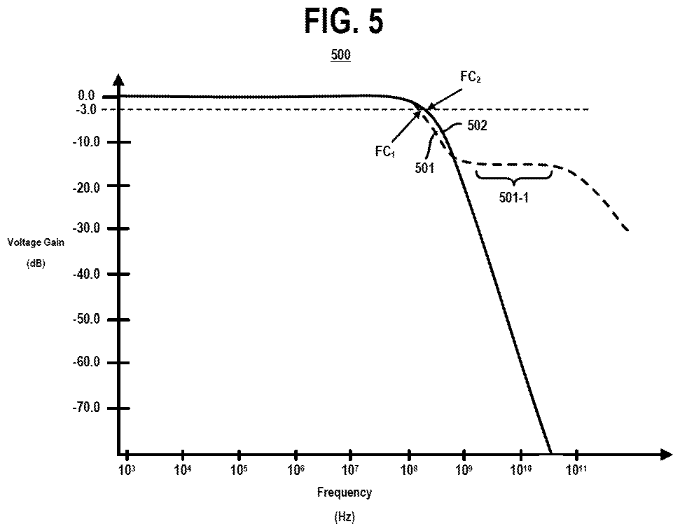

FIG. 5 graphically illustrates simulated responses of voltage-mode low-pass filters with and without output impedance neutralization, according to an exemplary embodiment of the disclosure. In particular, FIG. 5 is a graph 500 of voltage gain (dB) (y-axis) as a function of frequency (x-axis), which shows a first filter response curve 501 and a second filter response curve 502 of voltage-mode low-pass filters with unitary gain. In particular, the first filter response curve 501 depicts a simulated response of a voltage-mode low-pass filter which does not implement output impedance neutralization, while the second filter response curve 502 depicts a simulated response of the voltage-mode low-pass filter which implements output impedance neutralization.

In the exemplary simulated filter response curves of FIG. 5, the first filter response curve 501 has a cutoff frequency FC₁ (at a −3 dB point) of about 197.1 MHZ, and the second filter response curve 502 has a cutoff frequency FC₂ of about 226.4 MHZ. In addition, the first filter response curve 501 is shown to exhibit poor out-of-band rejection due to the nonzero output impedance of the single transistor M1 (active source follower stage) of the voltage-mode low-pass filter. For example, a portion 501-1 of the first filter response curve 501 includes a flat out-of-band response, which is undesirable. In contrast to the first filter response curve 501, FIG. 5 illustrates that the second filter response curve 502 has a sharper frequency response over a wider frequency range and exhibits greater out-of-band rejection due to the output impedance neutralization, which is highly desirable.

It is to be appreciated that the exemplary differential voltage-mode filter circuits with output impedance neutralization networks, such as shown in FIGS. 4A and 4B, provide various advantages over other filter circuit configurations as discussed herein. For example, the differential voltage-mode filter circuits with output impedance neutralization networks allow for ultra-low power, low supply voltage, and high-bandwidth voltage-mode filters with improved frequency responses (e.g., higher out-of-band rejection) as a result of neutralizing the negative effects on the filter frequency response that are due to the nonzero output impedance of the unity gain buffers of the voltage-mode filter circuits. For example, the first and second voltage-mode filter circuits 400-1 and 400-2 of the exemplary differential voltage-mode filter circuits 400 and 401 with output impedance neutralization networks, such as shown in FIGS. 4A and 4B, can each operate with low bias current (e.g., 60 microamps) and low power supply voltage (e.g., 675 mV) providing low power dissipation (e.g., about 40 micro watts), while effectively neutralizing the nonzero output impedances of the active source follower stages that are non-negligible with such low power operation.

Furthermore, the output impedance neutralization network 420 of the differential voltage-mode filter circuit 400 (or 401) has no impact on the DC biasing and common-mode compatibility with the DAC circuits coupled to the inputs of the differential voltage-mode filter circuit 400 and the RF output stage coupled to the outputs of the differential voltage-mode filter circuit 400. In particular, the output impedance neutralization network 420 comprises passive elements (e.g., resistors and capacitors) which do not require DC biasing. In addition, the output impedance neutralization network 420 is completely decoupled from the DC biasing of the first and second voltage-mode filter circuits 400-1 and 400-2 due to the neutralization capacitors C_{N} of the first and second neutralization impedance circuits 420-1 and 420-2. In this regard, the output impedance neutralization network 420 does not affect the differential voltage-mode filter circuit 400 in terms of DC current biasing. DC power consumption, and common-mode voltage levels—the DC biasing conditions are invariant.

For example, in the exemplary embodiment of FIG. 3, the common-mode voltage at the input node N1 (V_{IN_CM}) is set by the load resistor R_{L} and the average current output from the current source 305. The common-mode voltage at the output node N4 (V_{OUT_CM}) is higher than V_{IN_CM} by an amount equal to the source-to-gate voltage (V_{SG}) of the PMOS source follower transistor M1 of the voltage-mode filter circuit 300 (so V_{OUT_CM}=V_{IN_CM}+V_{SG}). The addition of the output impedance neutralization network 420 such as shown in FIG. 4A does not change V_{IN_CM} Or V_{OUT_CM} of the first and second voltage-mode filter circuits 400-1 and 400-2. Moreover, in the exemplary embodiment of FIG. 4B with the variable filter capacitors C₁ and C₂ and the variable neutralization capacitors C_{N}, the neutralization capacitors C_{N} can be tuned to track the filter capacitors C₁ and C₂, without having any effect on the DC biasing and common-mode voltages at the inputs and outputs of the differential voltage-mode filter circuit 401.

Another advantage is that the output impedance neutralization network 420 of the differential voltage-mode filter circuit 400 (or 401) eliminates the need to connect an additional buffer stage to the output nodes N4 of the first and second voltage-mode filter circuits 400-1 and 400-2 to improve the frequency response of the filters. As noted above, the output impedance neutralization network 420 serves to cancel transmission zeroes and add additional poles to the frequency responses of the first and second voltage-mode filter circuits 400-1 and 400-2, without the need for an additional buffer stage which would undesirably increase the power dissipation and footprint of the filter circuitry. Since no DC current flows through the neutralization capacitors C_{N}, the addition of the impedance neutralization network 420 has zero cost in static power dissipation.

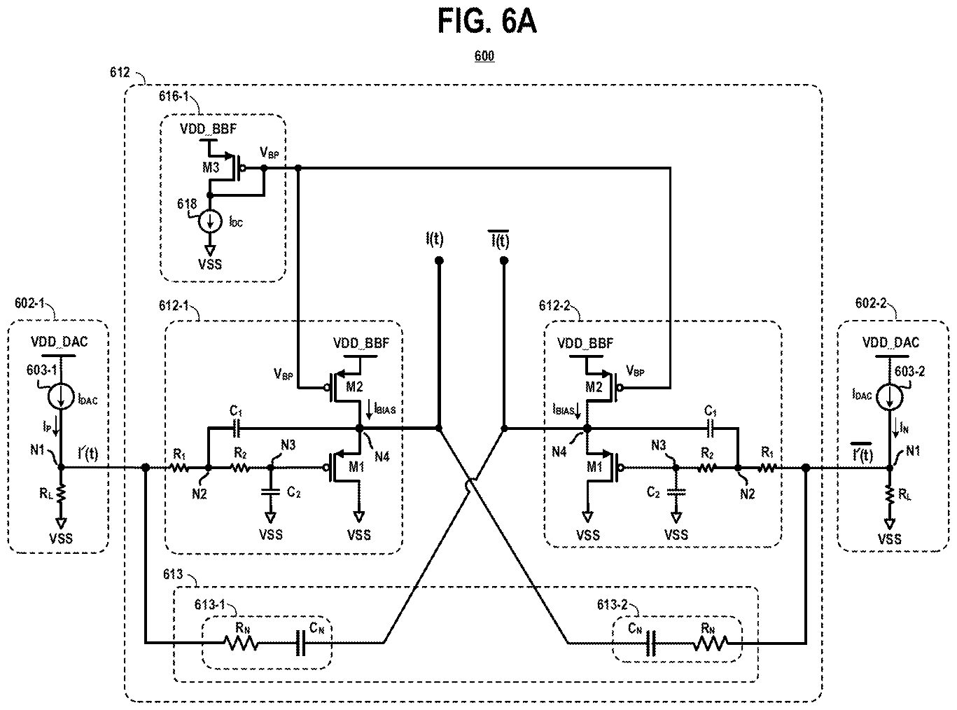

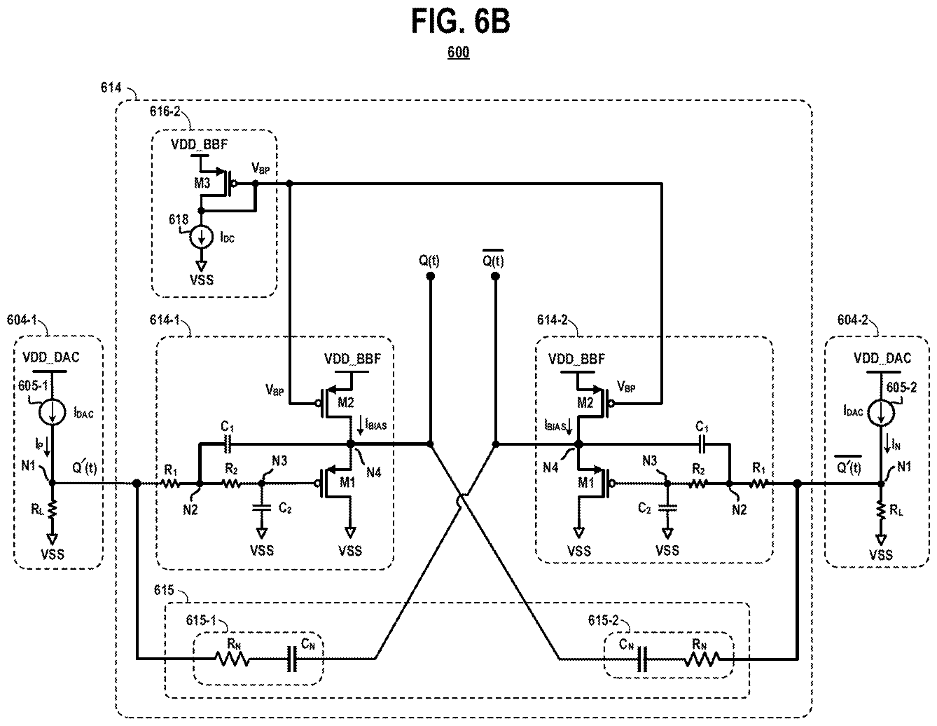

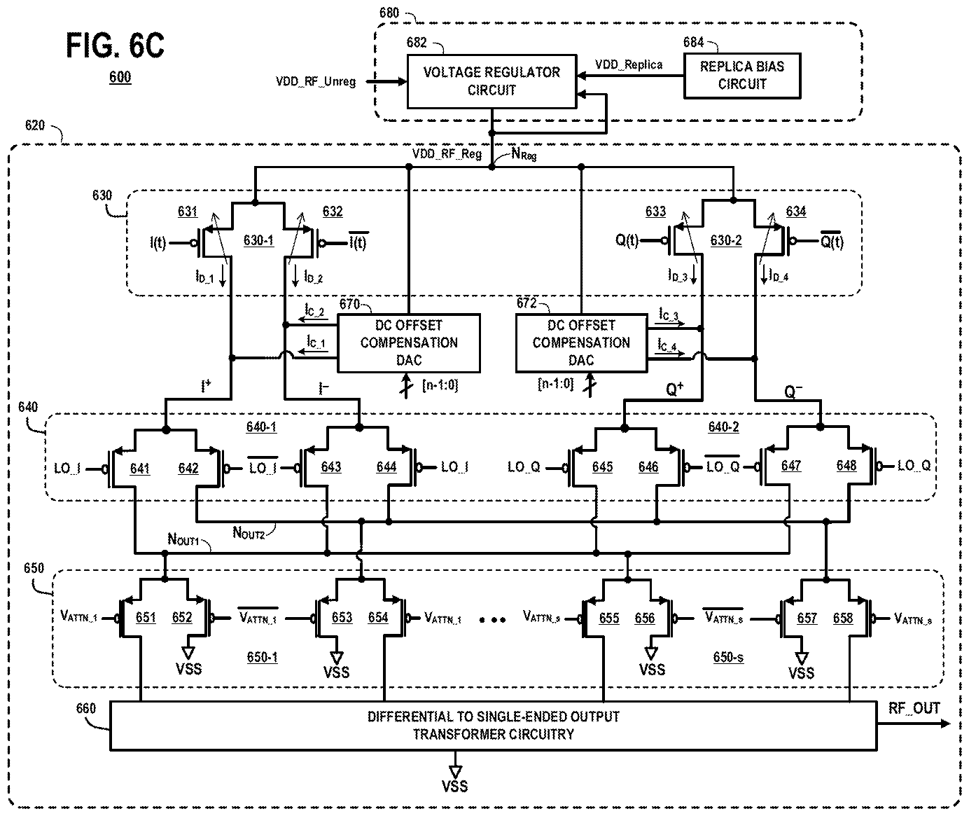

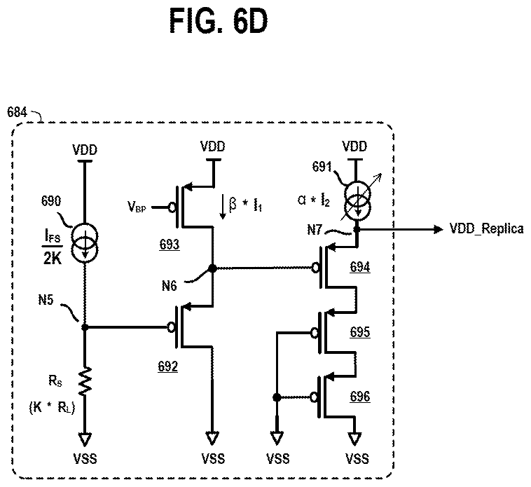

FIGS. 6A, 6B, 6C, and 6D schematically illustrate a radio frequency signal generator system, according to another exemplary embodiment of the disclosure. More specifically, 6A, 6B, 6C, and 6D schematically illustrate an RF signal generator system 600 which has a system architecture based on the RF signal generator system 200 of FIG. 2. FIGS. 6A and 6B collectively illustrate a voltage-mode filter stage comprising a first differential voltage-mode filter 612 (FIG. 6A) and a second differential voltage-mode filter 614 (FIG. 6B). The first differential voltage-mode filter 612 comprises a first voltage-mode filter circuit 612-1, a second voltage-mode filter circuit 612-2, a current reference circuit 616-1 comprising a reference current source 618, and a neutralization network 613 comprising a first neutralization impedance circuit 613-1 and a second neutralization impedance circuit 613-2. The second differential voltage-mode filter 614 comprises a first voltage-mode filter circuit 614-1, a second voltage-mode filter circuit 614-2, a current reference circuit 616-2 and a neutralization network 615 which comprises a first neutralization impedance circuit 615-1 and a second neutralization impedance circuit 615-2. The first and second differential voltage-mode filters 612 and 614 have the same circuit architecture, which is based on the exemplary architecture of the differential voltage-mode filter circuit 400 of FIG. 4A, the details of which will not be repeated.

Referring to FIG. 6A, the first differential voltage-mode filter 612 is configured to receive and filter respective complementary in-phase baseband voltage signals I′(t) and I̅′̅(̅t̅)̅, and output filtered complementary in-phase baseband voltage signals I(t) and I̅(̅t̅)̅. The complementary in-phase baseband voltage signals I′(t) and I̅′̅(̅t̅)̅ are output from respective first and second DAC circuits 602-1 and 602-2 (e.g., current steering DAC circuits), which have voltage-mode interfaces coupled to the input nodes N1 of the respective first and second voltage-mode filter circuits 612-1 and 612-2. The first and second DAC circuits 602-1 and 602-2 comprise respective current sources 603-1 and 603-2 which output complementary currents I_{P} and I_{N} to generate the complementary in-phase baseband voltage signals I′(t) and I̅′̅(̅t̅)̅, respectively (such as described above with respect to the DAC circuit 302, FIG. 3). In the exemplary embodiment of FIG. 6A, the first and second DAC circuits 602-1 and 602-2 comprise an I-DAC circuit 602 which converts complementary in-phase digital signals into the in-phase baseband voltage signals I′(t) and I̅′̅(̅t̅)̅.

Moreover, referring to FIG. 6B, the second differential voltage-mode filter 614 is configured to receive and filter respective complementary quadrature-phase baseband voltage signals Q′(t) and Q̅′̅(̅t̅)̅, and output filtered complementary quadrature-phase baseband voltage signals Q(t) and Q̅(̅t̅)̅. The complementary quadrature-phase baseband voltage signals Q′(t) and Q̅′̅(̅t̅)̅ are output from respective first and second DAC circuits 604-1 and 604-2 (e.g., current steering DAC circuits), which have voltage-mode interfaces coupled to the input nodes N1 of the respective first and second voltage-mode filter circuits 614-1 and 614-2. The first and second DAC circuits 604-1 and 604-2 comprise respective current sources 605-1 and 605-2 which output complementary currents I_{P} and I_{N} to generate the complementary quadrature-phase baseband voltage signals Q′(t) and Q̅′̅(̅t̅)̅, respectively (such as described above with respect to the DAC circuit 302, FIG. 3). In the exemplary embodiment of FIG. 6B, the first and second DAC circuits 604-1 and 604-2 comprises a Q-DAC circuit 604 which converts complementary quadrature-phase digital signals into the quadrature-phase baseband voltage signals Q′(t) and Q̅′̅(̅t̅)̅.

FIG. 6C schematically illustrates an exemplary embodiment of a current-mode RF output stage which can directly interface with the voltage-mode outputs of the first and second differential voltage-mode filters 612 and 614. More specifically, FIG. 6C schematically illustrates an exemplary embodiment of a current-mode RF output stage 620 which has an architecture based on the current-mode RF output stage 220 of FIG. 2. The current-mode RF output stage 620 comprises a baseband signal stage 630, a current-commutating mixer stage 640, a signal attenuation stage 650, a differential to single-ended output circuit 660 (alternatively, output transformer stage 660), a first DC offset compensation DAC 670, and a second DC offset compensation DAC 672. The RF signal generator system 600 further comprises a regulation system 680 which comprises a voltage regulator circuit 682, and a replica bias circuit 684, the functions of which will be explained in further detail below.

The baseband signal stage 630 comprises a plurality of baseband input transistors 631, 632, 633, and 634 (e.g., PMOS transistors). The baseband input transistors 631 and 632 comprise a first differential transistor pair 630-1, wherein the baseband input transistors 631 and 632 have source terminals that are commonly connected to an output terminal of the voltage regulator circuit 682, and respective gate terminals which receive the complementary baseband voltage signals I(t) and I̅(̅t̅)̅, respectively, which are output from the respective first and second voltage-mode filter circuits 612-1 and 612-2 of the first differential voltage-mode filter 612 (FIG. 6A). The baseband input transistors 633 and 634 comprise a second differential transistor pair 630-2, wherein the baseband input transistors 633 and 634 have source terminals that are commonly connected to the output terminal of the voltage regulator circuit 682, and respective gate terminals which receive the complementary baseband voltage signals Q(t) and Q̅(̅t̅)̅, respectively, which are output from the respective first and second voltage-mode filter circuits 614-1 and 614-2 of the second differential voltage-mode filter 614 (FIG. 6B). The baseband input transistors 631, 632, 633, and 634 each comprise a drain terminal that is connected to a respective one of a plurality of differential transistor pairs in the current-commutating mixer stage 640.

In some embodiments, the baseband input transistors 631, 632, 633, and 634 of the baseband signal stage 630 comprise variable gain elements (as schematically illustrated by the slanted arrows across the transistors) which are configurable to adjust the baseband signal gain in the I/Q signal paths, I⁺, I⁻, Q⁺, and Q⁻. For example, in some embodiments, each baseband input transistor 631, 632, 633, and 634 comprises a variable-width transistor that is structurally configured and controlled using known techniques to vary the effective gate width of the transistor structure and, thus, adjust a maximum amount of static DC drain current ID 1, ID 2, ID 3, and ID 4 (e.g., quiescent current) that flows through the respective baseband input transistors 631, 632, 633, and 634 when operating in saturation mode. In this regard, the baseband input transistors 631, in the 632, 633, and 634 are configured to enable transconductance (gₘ) tuning,

$${g}_{m} = \frac{Δ {I}_{OUT}}{Δ {V}_{IN}} ,$$

in the baseband signal stage 630.

For example, in some embodiments, each baseband input transistor 631, 632, 633, and 634 can be structurally configured to include a plurality of transistor segments that are coupled in parallel, wherein the number of segments that are active/inactive at a given time (via a digital switching control system) can be adjusted to change the effective gate width of a given baseband input transistor. In this regard, the effective widths of the baseband input transistors 631, 632, 633, and 634 in the baseband signal stage 630 can be configured to adjust the baseband signal gain in the I/Q signal paths I⁺, I⁻, Q⁺, and Q⁻ over a target gain range (e.g., gain range of 20 dB) with multiple gain step settings within the gain range. For example, in some embodiments, static DC baseband currents in the I/Q signal paths I⁺, I⁻, Q⁺, and Q⁻ can be adjusted to one of various target current levels over a given range wherein a highest baseband current level is about 10× greater than a lowest baseband current level (e.g., a range from about 35 uA to about 350 uA).

The current-commutating mixer stage 640 comprises a differential I mixer 640-1, and a differential Q mixer 640-2. The differential I mixer 640-1 comprises a plurality of mixing transistors 641, 642, 643, and 644 (alternatively, I mixer switching transistors 641, 642, 643, and 644). The differential Q mixer 640-2 comprises mixing transistors 645, 646, 647, and 648 (alternatively, Q mixer switching transistors 645, 646, 647, and 648). In some embodiments, as shown in FIG. 6C, the mixing transistors 641, 642, 643, 644, 645, 646, 647, and 648 are PMOS transistors. In some embodiments, the mixing transistors 641, 642, 643, 644, 645, 646, 647, and 648 are biased to operate in triode mode.

In the differential I mixer 640-1, the mixing transistors 641 and 642 comprise a first differential mixer transistor pair having source terminals that are commonly connected to the drain terminal of the baseband input transistor 631 in the baseband signal stage 630, and respective gate terminals which receive as input the complementary in-phase LO signals LO_I and L̅O̅_̅I̅, respectively. The mixing transistors 643 and 644 comprise a second differential mixer transistor pair having source terminals that are commonly connected to the drain terminal of the baseband input transistor 632 in the baseband signal stage 630, and respective gate terminals which receive as input the complementary in-phase LO signals L̅O̅_̅I̅ and LO_I, respectively.

In the differential Q mixer 640-2, the mixing transistors 645 and 646 comprise a first differential mixer transistor pair having source terminals that are commonly connected to the drain terminal of the baseband input transistor 633 in the baseband signal stage 630, and respective gate terminals which receive as input the complementary quadrature-phase LO signals LO_Q and L̅O̅_̅Q̅, respectively. The mixing transistors 647 and 648 comprise a second differential mixer transistor pair having source terminals that are commonly connected to the drain terminal of the baseband input transistor 634 in the baseband signal stage 630, and respective gate terminals which receive as input the complementary quadrature-phase LO signals L̅O̅_̅Q̅ and LO_Q, respectively.

The current-commutating mixer stage 640 comprises two output nodes, denoted N_{OUT1} and N_{OUT2}. As schematically shown in FIG. 6C, the mixing transistors 641, 643, 645, and 647 have drain terminals that are commonly coupled to the output node N_{OUT1} of the current-commutating mixer stage 640, and the mixing transistors 642, 644, 646, and 648 have drain terminals that are commonly coupled to the output node N_{OUT2} of the current-commutating mixer stage 640. The differential I mixer 640-1 and the differential Q mixer 640-2 are configured to provide analog I/Q modulation and upconversion, where the connections of the mixing transistors of the differential I and Q mixers 640-1 and 640-2 (operating in triode mode) allow for the summation/subtraction of the output currents of the mixing transistors 641, 642, 643, 644, 645, 646, 647, and 648 to achieve the SSB I/Q modulation, as is understood by those of ordinary skill in the art.

The signal attenuation stage 650 is configured to adjust a signal strength of the RF output signal, RF_OUT. More specifically, in the exemplary embodiment of FIG. 6C, the signal attenuation stage 650 is configured to adjust the amount of differential current that flows from the output nodes N_{OUT1} and N_{OUT2} to the output transformer stage 660. In this regard, the signal attenuation stage 650 is configured to adjust the signal level of the signal output from the current-commutating mixer stage 640. The signal attenuation stage 650 comprises a plurality of attenuation segments 650-1, . . . , 650-s which are digitally controlled by respective pairs of differential control signals [V_{ATTN}_{₁}, V̅_̅{̅A̅T̅T̅N̅}̅_̅{̅₁̅}̅], . . . [[V_{ATTN}_{ₛ}, V̅_̅{̅A̅T̅T̅N̅}̅_̅{̅ₛ̅}̅]. As schematically illustrated in FIG. 6C, the first attenuation segment 650-1 comprises a first differential pair of transistors 651 and 652, and a second differential pair of transistors 653 and 654. In addition, the attenuation segment 650-s comprises a first differential pair of transistors 655 and 656, and a second differential pair of transistors 657 and 658. In some embodiments, the transistors 651, 652, 653, 654, 655, 656, 657, and 658 of the signal attenuation stage 650 are PMOS transistors. The number(s) of attenuation segments 650-1, . . . , 650-s that are implemented will depend on the desired resolution of gain adjustment.

In the first attenuation segment 650-1, the first differential pair of transistors 651 and 652 have source terminals that are commonly connected to the mixer output node N_{OUT1}, and gate terminals that receive as input the differential control signals V_{ATTN}_{₁}, and V̅_̅{̅A̅T̅T̅N̅}̅_̅{̅₁̅}̅, respectively. The transistor 651 has a drain terminal that is coupled to the output transformer stage 660, and the transistor 652 has a drain terminal that is coupled to a negative power supply node VSS (e.g., 0V ground voltage). In addition, the second differential pair of transistors 653 and 654 have source terminals that are commonly connected to the mixer output node N_{OUT2}, and gate terminals that receive as input the differential control signals V̅_̅{̅A̅T̅T̅N̅}̅_̅{̅₁̅}̅ and V̅_̅{̅A̅T̅T̅N̅}̅_̅{̅₁̅}̅, respectively. The transistor 653 has a drain terminal that is coupled to the negative power supply node VSS, and the transistor 654 has a drain terminal that is coupled to the output transformer stage 660.

Similarly, in the attenuation segment 650-s, the first differential pair of transistors 655 and 656 have source terminals that are commonly connected to the mixer output node N_{OUT1}, and gate terminals that receive as input the differential control signals V_{ATTN}_{ₛ} and V̅_̅{̅A̅T̅T̅N̅}̅_̅{̅ₛ̅}̅, respectively. The transistor 655 has a drain terminal that is coupled to the output transformer stage 660, and the transistor 656 has a drain terminal that is coupled to a negative power supply node VSS. In addition, the second differential pair of transistors 657 and 658 have source terminals that are commonly connected to the mixer output node N_{OUT2}, and gate terminals that receive as input the differential control signals V̅_̅{̅A̅T̅T̅N̅}̅_̅{̅ₛ̅}̅ and V_{ATTN}_{ₛ}, respectively. The transistor 657 has a drain terminal that is coupled to the negative power supply node VSS, and the transistor 658 has a drain terminal that is coupled to the output transformer stage 660.

In operation, the amount of differential current that flows from the output nodes N_{OUT1} and N_{OUT2} to the output transformer stage 660 can be adjusted based on the number of attenuation segments 650-1, . . . , 650-s that are activated. A given attenuation segment is “activated” when the corresponding differential control signals V_{ATTN} and V̅_̅{̅A̅T̅T̅N̅}̅ are logic “0” and logic “1”, respectively. For instance, the first attenuation segment 650-1 will be activated when V_{ATTN}_{₁} is logic “0” and V̅_̅{̅A̅T̅T̅N̅}̅ is logic “1” such that the transistors 651 and 654 will be in a turned “On” state and allow some current to flow from the output nodes N_{OUT1} and N_{OUT2} to the output transformer stage 660, while the transistors 652 and 653 will be in a turned “Off state. On the other hand, the first attenuation segment 650-1 will be “deactivated” when V_{ATTN}, is logic “1” and V̅_̅{̅A̅T̅T̅N̅}̅ is logic “0” such that the transistors 651 and 654 will be in a turned “Off” state, and the transistors 652 and 653 will be in a turned “On” state and allow some current to flow from the output nodes N_{OUT1} and N_{OUT2} to the negative power supply node VSS (e.g., ground). Since the current flowing from the output nodes N_{OUT1} and N_{OUT2} to the negative power supply node VSS (e.g., ground) does not contribute to the current flowing through the output transformer stage 660, the RF output signal level is reduced.

In this configuration, the amount of differential current that flows from the output nodes N_{OUT1} and N_{OUT2} to the output transformer stage 660 can be increased by increasing the number of activated attenuation segments, or decreased by decreasing the number of activated attenuation segments. The number(s) of attenuation segments 650-1, . . . , 650-s that are implemented will depend on the desired resolution of gain adjustment. It is to be noted that when activated, the transistors of the signal attenuation stage 650 are configured to operate in saturation mode.

In the exemplary I/Q modulation architecture of the RF signal generator system 600 shown in FIGS. 6A-6D, it is desired to eliminate or otherwise substantially minimize imbalance between the baseband I and Q signals for purposes of image rejection. Indeed, an I/Q imbalance can result in an unwanted spectrum at the image frequency. As noted above, an SSB mixer is configured to upconvert an intermediate frequency (IF) of the baseband signals to only one of sideband signal center frequencies of LO+IF or LO−IF, without creating an image of the other sideband signal, which is particularly useful when using low IF frequencies, as frequency-selective filtering is difficult in that case. For example, if a desired RF signal is to be generated at frequency f_{RF}=f_{LO}−f_{IF}, then the sideband signal (image signal) at f_{IF}+f_{LO} will be suppressed by the sideband suppression provided by the SSB mixer. However, an imbalance in the amplitude of the baseband I and Q signals can result in the presence of relatively high spectral power for the unwanted spectrum at the image frequency.

Furthermore, for differential I/Q schemes which utilize differential analog I signals (I(t), I̅(̅t̅)̅) and differential analog Q signals (Q(t), Q̅(̅t̅)̅), an imbalance between the differential analog I signals I(t) and I̅(̅t̅)̅ and/or an imbalance between the differential analog Q signals Q(t) and Q̅(̅t̅)̅, can result in LO leakage. For example, an imbalance between the differential analog baseband signals I(t) and I̅(̅t̅)̅ and/or the differential analog baseband signals Q(t) and Q̅(̅t̅)̅ can be a DC offset of the baseband analog signals generated by the DAC stage 120. A DC offset between differential baseband signals means that the signals are not completely complementary due to the existence of a DC term. In the current-commutating mixer stage 640, the DC offset of a complementary baseband signal pair results in a DC term that is multiplied by the LO frequency, so that the output of the current-commutating mixer stage 640 comprises an unwanted LO frequency component (LO leakage), which should otherwise be suppressed by virtue of the I/Q modulation.

In some embodiments, the first DC offset compensation DAC 670 and the second DC offset compensation DAC 672 are utilized to correct for imbalances between the static currents I_{D_1}, I_{D_2}, I_{D_3}, and I_{D_4} that flow into the I/Q signal paths I⁺, I⁻, Q⁺, and Q⁻, respectively, under control of a calibration control system (e.g., the calibration control system 190 of FIG. 1). As schematically shown in FIG. 6C, the first DC offset compensation DAC 670 comprises a first output terminal coupled to the drain terminal of the baseband input transistor 631, and a second output terminal coupled to the drain terminal of the baseband input transistor 632. The second DC offset compensation DAC 672 comprises a first output terminal coupled to the drain terminal of the baseband input transistor 633, and a second output terminal coupled to the drain terminal of the baseband input transistor 634.

In this exemplary configuration, in response to a control signal (e.g., n-bit digital control signal [n−1:0]) received from a calibration control system, the first DC offset compensation DAC 670 is configured to inject additional currents I_{C_1} and I_{C_2} into the I′ and I′ signal paths, as needed to compensate for any offset between the static bias currents I_{D_1} and I_{D_2}. In particular, the additional currents I_{C_1} and I_{C_2} are added to the respective static bias currents I_{D_1} and I_{D_2} that are generated by the respective baseband input transistors 631 and 632 to thereby equalize the static I⁺ and I⁻ baseband currents and, thus, significantly reduce or eliminate any DC offset between the static I⁺ and I⁻ baseband currents that are applied to the input of the I-mixer 640-1. Similarly, in response to a control signal (e.g., n-bit digital control signal [n−1:0]) received from the calibration control system, the second DC offset compensation DAC 672 is configured to inject additional currents I_{C_3} and I_{C_4} into the Q⁺ and Q⁻ baseband signal paths, as needed to compensate for any offset between the static bias currents I_{D_3} and I_{D_4}. In particular, the additional currents I_{C_3} and I_{C_4} are added to the respective static bias currents I_{D_3} and I_{D_4} that are generated by the baseband input transistors 633 and 634 to thereby equalize the static Q⁺ and Q⁻ baseband currents and, thus, significantly reduce or eliminate any DC offset between the static Q⁺ and Q⁻ baseband currents that are applied to the input of the Q-mixer 640-2.

In the baseband signal stage 630, matching is critical between the first differential pair of baseband input transistors 631 and 632, and between the second differential pair of baseband input transistors 633 and 634. In addition, matching is critical between the first differential transistor pair 630-1 and the second differential transistor pair 630-2. Mismatches between the transistors in the baseband signal stage 630 can cause an imbalance in the I/Q baseband current signals, which can lead to LO leakage and insufficient image rejection. In some embodiments, a calibration control system (e.g., calibration control system 190 of FIG. 1) implements control circuitry and calibration methods for configuring the RF signal generator system 600 to operate in a calibration mode, wherein the calibration control system can measure the static currents I_{D_1}, I_{D_2}, I_{D_3}, and I_{D_4} that flow into the I/Q signal paths I⁺, I⁻, Q⁺, and Q⁻ and determine a difference between the same phase pairs {I⁺, I⁻} and {Q⁺, Q⁻}, which provides an indication of DC offsets that lead to LO leakage and determine a difference (imbalance) between the measured I⁺ and Q⁺ baseband currents, wherein an imbalance between the I⁻ and Q⁻ baseband currents can degrade image rejection, which results in the presence of unwanted sideband spurs.

It is to be noted that imbalances between the static baseband currents can be adjusted via the first and second DC offset compensation DACs 670 and 672, and/or the I-DAC circuits 602-1 and 602-2 (FIG. 6A) and the Q-DAC circuits 604-1 and 604-2 (FIG. 6B). For example, utilizing the first and second DC offset compensation DACs 670 and 672 in the current-mode RF output stage 620 ensures that any imbalance (offsets) between two static baseband currents corresponding to a given phase, e.g., {I⁺ and I⁻}, and {Q⁺ and Q⁻} is minimized. On the other hand, in some embodiments, DC offset compensation DACs can be used to inject compensation currents into the voltage-mode output interfaces of the I-DAC circuits 602-1 and 602-2 (FIG. 6A) and the Q-DAC circuits 604-1 and 604-2 (FIG. 6B) to correct for an imbalance between the baseband currents I⁺ and Q⁺. Thus, utilizing the first and second DC offset compensation DACs 670 and 672 in the current-mode RF output stage 620, together with DC offset compensation implemented with the I-DAC and Q-DAC circuits 602 and 604 provides the ability to correct for imbalances and ensure that all static baseband currents I⁺, I⁻, Q⁺, and Q⁻ are essentially equal in magnitude.

With the exemplary architecture of the RF signal generator system 600 as shown in FIGS. 6A-6D, the output nodes N4 of the single-ended voltage-mode baseband filter circuits 612-1, 612-2, 614-1, and 614-2 are directly connected (DC-coupled) to the gate terminals of the respective baseband input transistors 631, 632, 633, and 634 of the baseband signal stage 630 of the current-mode RF output stage 620. It is to be noted, however, that interfacing the single-ended voltage-mode baseband filter circuits 612-1, 612-2, 614-1, and 614-2 with the baseband signal stage 630 is not trivial because directly connecting the voltage-mode outputs of baseband filter transistors to the transistors in the baseband signal stage 630 typically does not provide for suitable biasing of transistors in the current-mode RF output stage 620 (unlike current-mode connections, which are provided between a current-mode baseband filter and current-mode output stage, based on current mirrors).

In particular, the quiescent currents (e.g., I_{D1}, I_{D2}, I_{D3}, and I_{D4}) generated by the baseband input transistors 631, 632, 633, and 634 of the baseband signal stage 630 of the current-mode RF output stage 620 are especially sensitive to supply voltage variations in instances where the output common-mode voltage of the each of the voltage-mode baseband filter circuits 612-1, 612-2, 614-1, and 614-2 is ground-referenced (e.g., referenced to VSS), while the biasing of the baseband input transistors 631, 632, 633, and 634 of the baseband signal stage 630 is referenced to the positive supply (e.g. referenced to VDD). More specifically, the DC biasing of the baseband input transistors 631, 632, 633, and 634 of the baseband signal stage 630 is based on the V_{SG} bias voltages of the baseband input transistors 631, 632, 633, and 634, wherein the V_{SG} biasing is referenced to the positive power supply VDD. On the other hand, the output common-mode voltages of the single-ended voltage-mode baseband filter circuits 612-1, 612-2, 614-1, and 614-2 are essentially ground-referenced (referenced to VSS) and, thus, do not rely on the positive power supply. In this regard, since the output common-mode voltages of the single-ended voltage-mode baseband filter circuits 612-1, 612-2, 614-1, and 614-2 are directly applied to the gate terminals of the respective baseband input transistors 631, 632, 633, and 634, variations in the positive power supply voltage VDD will result in V_{SG} voltage variations of the baseband input transistors 631, 632, 633, and 634, which, in turn, results in variations in the quiescent currents (or bias currents) that flow in the analog I/Q signal paths of the current-mode RF output stage 620. In other words, since the V_{SG} biasing of the baseband input transistors 631, 632, 633, and 634 is based on the difference between the output common-mode voltages of the single-ended voltage-mode baseband filter circuits 612-1, 612-2, 614-1, and 614-2 and the power supply voltage VDD, the quiescent currents I_{D1}, I_{D2}, I_{D3}, and I_{D4} generated by the baseband input transistors 631, 632, 633, and 634 are highly sensitive to variations in the power supply voltage VDD, which can result in unstable bias points of the current-mode RF output stage 620.

In this regard, various techniques can be implemented to interface the voltage-mode baseband filter circuits to the current-mode RF output stage 620 while ensuring that the quiescent currents (e.g., I_{D1}, I_{D2}, I_{D3}, and I_{D4}) generated by the baseband input transistors 631, 632, 633, and 634 in the baseband signal stage 630 remain constant at target current levels. In general, such techniques provide a mechanism for adjusting the voltage at the source nodes of the first differential transistor pair 630-1, and the source nodes of the second differential transistor pair 630-2, so that baseband input transistors 631, 632, 633, and 634 are biased at the proper gate-to-source voltage (V_{SG}) in saturation mode to achieve the desired quiescent current levels (e.g., I_{D1}, I_{D2}, I_{D3}, and I_{D4}) for biasing the current-mode RF output stage 620.

FIG. 6C illustrates an exemplary embodiment in which the regulation system 680 is configured to generate a regulated positive supply voltage, denoted VDD_RF_Reg, which is applied to a regulated voltage node, denoted N_{Reg} (alternatively, regulated node N_{Reg}) to which the source nodes of the baseband input transistors 631, 632, 633, and 634 are commonly connected. More specifically, in the exemplary embodiment of FIG. 6C, the voltage regulator circuit 682 and the replica bias circuit 684 are configured to operate in conjunction to generate the regulated positive supply voltage VDD_RF_Reg which is applied to the regulated node N_{Reg}, thereby enabling the interfacing of the first and second differential voltage-mode filters 612 and 614 with the current-mode RF output stage 620, while providing a well-controlled bias point for the current-mode RF output stage 620. The replica bias circuit 684 is configured to generate a reference voltage, VDD_Replica, which is input to the voltage regulator circuit 682 and utilized to generate a regulated voltage VDD_RF_Reg on the regulated node N_{Reg}, relative to the output common-mode voltage levels on the output nodes of the single-ended voltage-mode baseband filter circuits 612-1, 612-2, 614-1, and 614-2 to thereby maintain a constant V_{SG} for the baseband input transistors 631, 632, 633, and 634 and, thus, maintain a well-controlled quiescent current in the I/Q signal paths of the current-mode RF output stage 620 to achieve a stable bias point of the current-mode RF output stage 620.

In some embodiments, the voltage regulator circuit 682 comprises a low-dropout (LDO) voltage regulator circuit which is configured to receive as input (i) an unregulated positive supply voltage VDD_RF_Unreg and (ii) a reference voltage VDD_Replica which is output from the replica bias circuit 684, and generate the regulated supply voltage VDD_RF_Reg which corresponds to VDD_Replica. An LDO voltage regulator circuit is a DC linear voltage regulator that is configured to regulate the LDO output voltage (VDD_RF_Reg) even when the unregulated positive supply voltage VDD_RF_Unreg is close to the LDO output voltage. In some embodiments, VDD_RF_Unreg is a supply voltage of about 900 mV or less, which is applied from a positive power supply node. The voltage regulator circuit 682 monitors the voltage on the regulated node N_{Reg} and actively adjusts the regulated supply voltage VDD_RF_Reg to ensure that VDD_RF_Reg corresponds to VDD_Replica. In this regard, the regulation system 680 is configured to actively regulate the voltage on the regulated node N_{Reg} to correspond to VDD_Replica, which is set by the replica bias circuit 684.

In some embodiments, the replica bias circuit 684 comprises a replica of circuit components of the voltage-mode baseband filter and of the RF output stack. In this regard, the replica bias circuit 684 will vary depending on the circuit architecture of the voltage-mode baseband filter and the RF output stack. For example, FIG. 6D schematically illustrates an exemplary embodiment of the replica bias circuit 684, which comprises replica elements that correspond to the components of the voltage-mode baseband filter and current-mode RF output stage 620. In particular, in the exemplary embodiment of FIG. 6D, the replica bias circuit 684 comprises a first replica current source 690, a second replica current source 691, a replica resistor R_{S}, and replica transistors 692, 693, 694, 695, and 696. The first replica current source 900 and the replica resistor R_{S} correspond to the DAC current source and the load resistor R_{L}, respectively, of one instance of the voltage-mode interface between a DAC circuit and voltage-mode baseband filter circuit. The replica transistors 692 and 693 correspond to the transistors M1 and M2, respectively, of one instance of the voltage-mode baseband filter circuit (e.g., 612-1, 612-2, 614-1, and 614-2). The replica transistor 694 corresponds to one instance of the baseband input transistors of the baseband signal stage 630. The replica transistor 695 corresponds to one instance of the LO switching transistors in the current-commutating mixer stage 640. The replica transistor 696 corresponds to one instance of the transistors in the signal attenuation stage 650. It is to be noted that because the DC voltage drop across the output transformer stage 660 is negligible, the wiring resistance of the output transformer stage 660 does not need to be included in the replica bias circuit 684.

To match a common-mode voltage on node N5 with a common-mode voltage on node N1, the first replica current source 690 is configured to generate a bias current of magnitude I_{FS}/2K, where I_{FS} denotes a full-scale DAC current, and K denotes a scalar multiplier, where K>>1. The replica resistor R_{S} has a resistance value of K*R_{L}. In this regard, the first replica current source 690 and the replica resistor R_{S} are configured to generate an input common-mode voltage on node N5 of the replica bias circuit 684 which matches the input common-mode voltage that is generated on the input node N1 of the voltage-mode filter circuit. The input common-mode voltage on node N5 biases the gate terminal of the replica transistor 692. The replica bias circuit 684 is configured to generate a bias current of magnitude β*I₁ which flows in the current path through the replica transistors 693 and 692 (which operate in saturation mode), where I₁ denotes the bias current of the voltage-mode filter circuit which flows through the transistors M2 and M1 operating in saturation mode, and β denotes a scalar multiplier, where β<<1.

The second replica current source 691 is configured to generate a bias current of magnitude α*I₂ which flows in the current path through the replica transistors 694, 695, and 696, where I₂ denotes the desired bias current of the current-mode RF output stage 620, and a denotes a scalar multiplier, where α<<1. In the replica bias circuit 684, the replica transistors 694 and 696 are configured to operate in saturation mode (similar to the transistors in the baseband signal stage 630 and the signal attenuation stage 650), while the replica transistor 695 is configured to operate in triode mode (similar to the mixing transistors in the current-commutating mixer stage 640). In some embodiments, the second replica current source 691 is a variable current source which allows for adjustment of the bias current of magnitude α*I₂ in response to an adjustment of the desired bias current I₂ of the current-mode current-mode RF output stage 620, such as when the gain of the baseband signal stage 630 is scaled (increased or decreased) to change the output amplitude of the RF output signal.

The replica transistors 692, 693, 694, 695, and 696 have width/length (W/L) dimension ratios that are designed based on the W/L dimension ratios of the corresponding transistors in the voltage-mode filter circuit and the current-mode RF output stage. For example, the W/L dimension ratios of the replica transistors are designed accordingly based on the following: α(W/L), where W/L denotes the dimension ratio of the circuit transistors, and α denotes a scaling factor. In particular, the replica transistors 694, 695, and 696 in the replica bias circuit 684 are scaled versions of corresponding transistors in baseband input stage 630, the current-commutating mixer stage 640, and the attenuation stage 650. The replica transistors are scaled by the same scaling factor α to ensure that the current density remains the same between the current-mode RF output stage 620 and the replica bias circuit 684.

The dimensions of the replica transistors 692 and 693 are configured so that the replica bias circuit 684 generates a voltage on node N6 which corresponds to the output common-mode voltages generated on the nodes N4 of the single-ended voltage-mode baseband filter circuits 612-1, 612-2, 614-1, and 614-2, which are applied to the gate terminals of the respective baseband input transistors 631, 632, 633, and 634. In addition, the dimensions of the replica transistors 694, 695, and 696 are configured so that the replica bias circuit 684 generates the reference voltage, VDD_Replica, on node N7, which corresponds to the voltage that needs to be applied to the regulated node N_{Reg}, relative to the output common-mode voltages of the single-ended voltage-mode baseband filter circuits 612-1, 612-2, 614-1, and 614-2 to establish the proper V_{SG} bias voltages for baseband input transistors 631, 632, 633, and 634 to obtain a constant and stable bias current I₂ that is generated by the baseband signal stage 630 to properly bias the current-mode RF output stage 620.

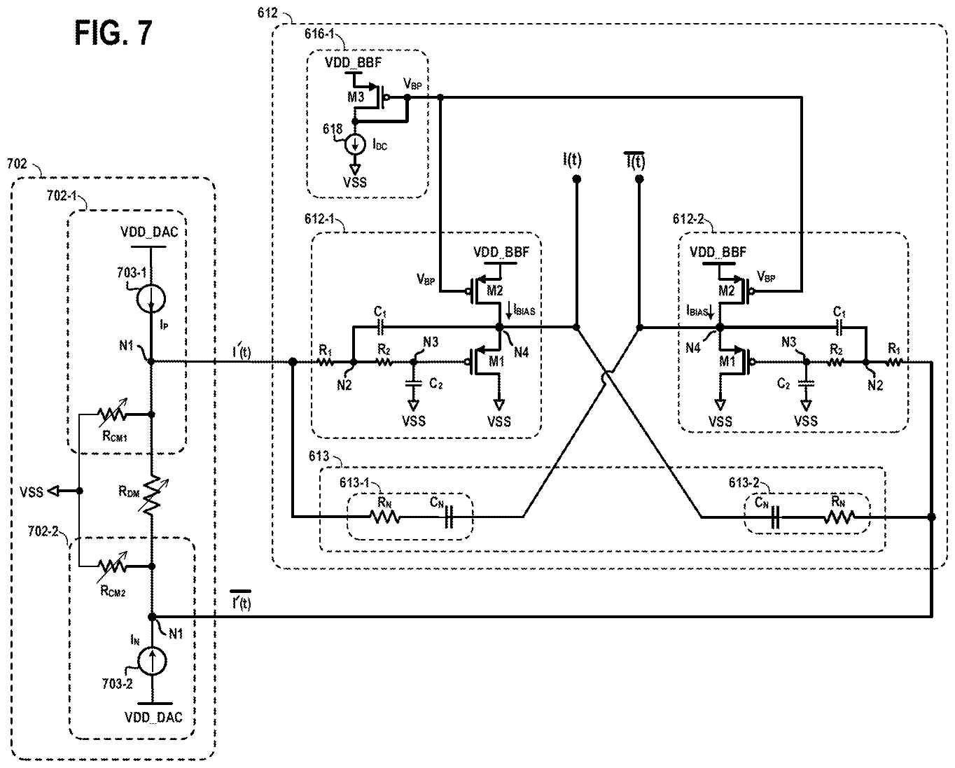

As noted above, in some embodiments, the baseband input transistors 631, 632, 633, and 634 of the baseband signal stage 630 (FIG. 6C) comprise variable gain elements which can be configured (via digital control signals) to adjust the baseband signal gain in the I/Q signal paths, I+, I−, Q+, and Q−. In other embodiments, a gain control system can be implemented at the voltage interfaces between the DAC circuits and the voltage-mode filter circuits to provide, e.g., fine gain control (via variable load resistors), while utilizing the baseband signal stage 630 to provide coarse gain control by, e.g., enabling a variable number of segments of the baseband input transistors 631, 632, 633, and 634. For example, FIG. 7 schematically illustrates a gain control system which is implemented at interfaces between DAC circuits and voltage-mode filter circuits of an RF signal generator system, according to an exemplary embodiment of the disclosure. More specifically, FIG. 7 schematically illustrates an exemplary embodiment of a DAC circuit 702 (e.g., I-DAC circuit) which is coupled to a differential voltage-mode filter (e.g., the first differential voltage-mode filter 612, FIG. 6A), wherein the DAC circuit 702 comprises variable load resistors that can be programmatically tuned to enable fine gain control in a baseband signal path (e.g., I signal path), according to an exemplary embodiment of the disclosure.

As schematically illustrated in FIG. 7, the DAC circuit 702 comprises a first DAC circuit 702-1 and a second DAC circuit 702-2. The first DAC circuit 702-1 comprises a current source 703-1 which generates a DAC current I_{P}. and a voltage-mode output interface which comprises a variable resistor Remi that is configured to set a common mode voltage at the input node N1 of the first single-ended voltage-mode baseband filter circuit 612-1. The second DAC circuit 702-2 comprises a current source 703-2 which generates a DAC current I_{N} (which is complementary to the DAC current I_{P}) and a voltage-mode output interface which comprises a variable resistor R_{CM2} that is configured to set a common mode voltage at the input node N1 of the second single-ended voltage-mode baseband filter circuit 612-2. In addition, the voltage-mode output interface of the DAC circuit 702 comprises a variable resistor R_{DM} which is connected between the input nodes N1 of the first and second voltage-mode filter circuits 612-1 and 612-2.

In the exemplary circuit configuration of FIG. 7, the resistance values of the variable resistors R_{CM1} and R_{CM2} can be tuned or otherwise calibrated using calibration control signals to adjust the magnitude of the common-mode voltage at the input nodes N1 of the first and second voltage-mode filter circuits 612-1 and 612-2. More specifically, the resistance values of the variable resistors R_{CM1} and R_{CM2} can be increased/decreased to increase/decrease the common-mode voltage at the input nodes N1 of the first and second voltage-mode filter circuits 612-1 and 612-2. In addition, the resistance value of the variable resistor R_{DM} can be tuned or otherwise calibrated using calibration control signals to adjust the magnitude of a differential voltage (e.g., differential voltage swing) between the input nodes N1 of the first and second voltage-mode filter circuits 612-1 and 612-2.

In the absence of the variable resistor R_{DM}, the magnitude of the differential voltage swing between the input nodes N1 of the first and second voltage-mode filter circuits 612-1 and 612-2 would increase/decrease when the common-mode voltages at the input nodes N1 were increased/decreased. Indeed, in this instance, the amplitude of the output voltage on the nodes N1 would depend on the resistance values of the load resistors R_{CM1} and R_{CM2} with a V=IR relationship, e.g., a larger amplitude voltage would be generated on the nodes N1 if the resistance values of the load resistors R_{CM1} and R_{CM2} were increased, which would lead to a larger differential voltage swing between the input nodes N1 of the first and second voltage-mode filter circuits 612-1 and 612-2 (which may be undesirable).

The variable resistor Rpm provides a mechanism for adjusting the magnitude of the differential voltage between the input nodes N1 of the first and second voltage-mode filter circuits 612-1 and 612-2, independent of the common-mode voltage adjustment achieved by tuning the variable load resistors R_{CM1} and R_{CM2}. Indeed, with regard to the differential voltage tuning, the variable resistor Rpm is parallel to each of the variable resistors R_{CM1} and R_{CM2} and, consequently, the variable resistor Rpm serves to reduce the differential voltage swing between the input nodes N1. In effect, the implementation of the variable resistor R_{DM} breaks the link between the common-mode voltage (for purposes of DC bias) and the differential voltage swing and, therefore, provides a second degree of freedom for adjusting the differential voltage swing at the input nodes N1 of the first and second voltage-mode filter circuits 612-1 and 612-2.

While FIG. 7 illustrates an exemplary embodiment for providing fine tuning of the baseband voltage signal gain in the I signal path, the same techniques would be applied to enable fine tuning of the baseband voltage signal gain in the Q signal path. For example, a Q DAC circuit similar to the I DAC circuit 702 would be implemented (in FIG. 6B) with variable resistors to enable adjustment of the magnitudes of (i) the common-mode voltages at the input nodes N1 of the first and second voltage-mode filter circuits 614-1 and 614-2, and (ii) the differential voltage swing between the input nodes N1 of the first and second voltage-mode filter circuits 614-1 and 614-2. The exemplary gain control techniques shown in FIG. 7 allow fine voltage gain adjustment of the complementary in-phase baseband voltage signals I(t) and I̅(̅t̅)̅ and the complementary quadrature-phase baseband voltage signals Q(t) and Q̅(̅t̅)̅, which are output from the first and second differential voltage-mode filters 612 and 614 and applied to the inputs of the baseband signal stage 630. While the first and second differential voltage-mode filters 612 and 614 comprise unity gain filters, the fine voltage gain adjustment in the baseband I/Q signal paths is achieved through tuning of the load resistors of the I and Q DACs, while coarse gain adjustment in the baseband I/Q signal paths is achieved by the transconductance (gₘ) tuning,

$${g}_{m} = \frac{Δ {I}_{OUT}}{Δ {V}_{IN}} ,$$

in the baseband signal stage 630.

It is to be appreciated that the exemplary radio frequency signal generation systems as described herein are configured to operate at relatively low power supply voltage and low power consumption (e.g., milliwatt range), which allows the radio frequency signal generation systems to be implemented with cryo-electronics that are used for quantum computing applications and other applications or systems which operate at cryogenic temperatures. For example, in the context of quantum computing systems which implement superconducting qubits and other components, the exemplary radio frequency signal generation systems as discussed herein can be implemented as an AWG system that is configured to generate RF control pulses to control superconducting qubits to perform high-fidelity qubit gate operations (e.g., single-qubit gate operations, entanglement gate operations, etc.).

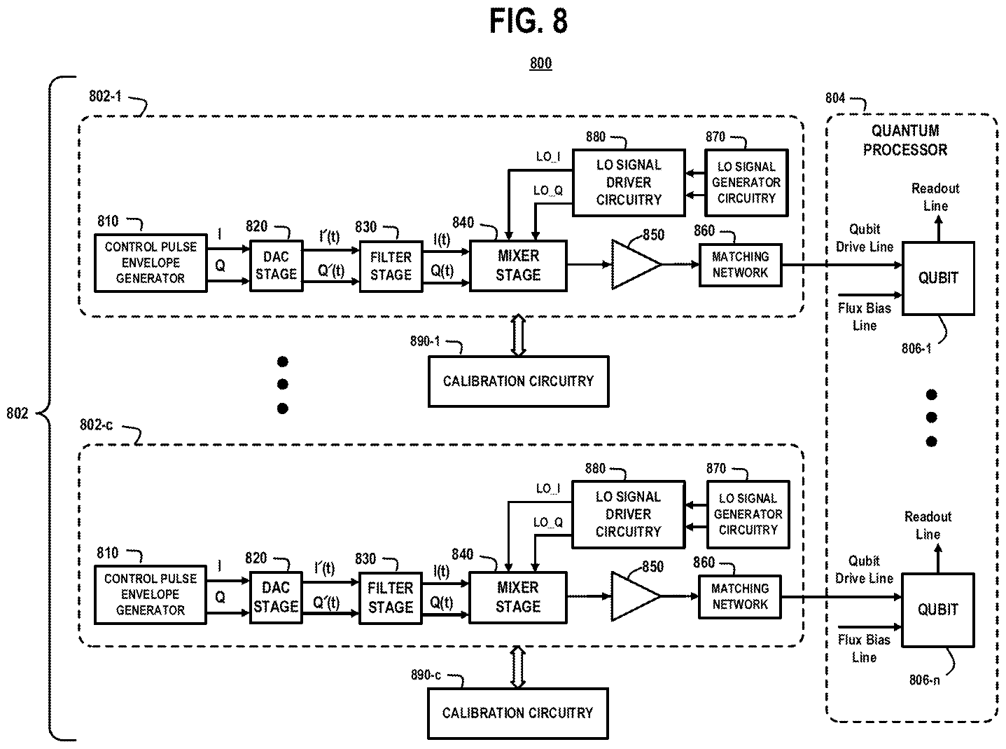

For example, FIG. 8 schematically illustrates a quantum computing system 800 which implements an arbitrary waveform generator system and calibration circuitry, according to an exemplary embodiment of the disclosure. The quantum computing system 800 comprises an arbitrary waveform generator system 802 (or AWG system 802) and a quantum processor 804. The quantum processor 804 comprises a plurality (n) of superconducting qubits 806-1, . . . 806-n. The superconducting qubits 806-1, . . . , 806-n may comprise superconducting transmon qubits, superconducting fluxonium qubits, superconducting multi-mode qubits, and other types, or combinations of different types, of superconducting qubits, which are suitable for a given application. Further, in some embodiments, the quantum processor 804 comprises coupler circuits (e.g., passive coupler circuits and/or active coupler circuits), wherein a given coupler circuit is configured to couple a pair of superconducting qubits to implement entanglement gate operations (e.g., two-qubit gate operations).

The quantum processor 804 further comprises a plurality of control lines (e.g., transmission line resonators) including, but not limited to, qubit drive lines, flux bias lines, state readout lines, and active coupler drive lines, etc. In some embodiments, the qubit drive lines are coupled (e.g., capacitively coupled) to respective ones of the superconducting qubits 806-1, . . . 806-n. The qubit drive lines are configured to apply control pulses (which are generated by the AWG system 802) to the respective superconducting qubits 806-1, . . . , 806-n to independently change the states of the respective superconducting qubits (e.g., single-qubit gate operations), e.g., change the state of a given superconducting qubit to be in, e.g., a ground state |0>, an excited state |1>, or a superposition state. As is known in the art, the state of a superconducting qubit can be changed by applying a microwave control pulse with a center frequency that is equal to a transition frequency (denoted for) of the qubit, wherein the transition frequency f₀₁ corresponds to an energy difference between the ground state |0> and excited state |1> of the qubit. In some embodiments, the superconducting qubits 806-1, . . . , 806-n are configured to have different operating frequencies (transition frequencies) so that the transition frequencies of neighboring qubits are detuned.

The state readout lines are coupled to respective ones of the superconducting qubits 806-1, . . . , 806-n to read the states of the superconducting qubits using known techniques (e.g., dispersive readout). In embodiments where the superconducting qubits comprise frequency-tunable qubits (e.g., flux-tunable transmon qubits or fluxonium qubits, etc.), the flux bias control lines would be coupled (e.g., inductively coupled) to respective superconducting qubits to apply flux bias control signals to tuning structures of the superconducting qubits to tune the operating frequencies of the tunable qubits, as needed for a given application. In addition, for active coupler circuits, coupler drive lines would be coupled (e.g., capacitively coupled) to respective coupler circuits, wherein each coupler circuit would have an operating frequency or transition frequency. A given coupler circuit would be driven by a control pulse generated by the AWG system 802, or some other pulse signal generator, to enable exchange coupling between superconducting qubits that are coupled through the given coupler circuit and implement a two-qubit gate operation.

As shown in FIG. 8, the AWG system 802 comprises a multi-channel AWG framework which comprises a plurality of AWG channels 802-1, . . . , 802-c. The AWG channels 802-1, . . . , 802-c are configured to generate control pulses that are applied on the qubit drive lines to control respective ones of the superconducting qubits 806-1, . . . , 806-n. Although not specifically shown in FIG. 8, in some embodiments, the AWG system 802 would include AWG channels to generate control signals that are applied to the coupler drive lines to control active coupler devices of the quantum processor 804.

The AWG channels 802-1, . . . , 802-c each comprise a respective control pulse envelope generator 810, a DAC stage 820, a filter stage 830, an I/Q mixer stage 840, an amplifier/attenuator stage 850, a matching network 860, an LO signal generator circuit 870, and an LO signal driver circuit 880. The control pulse envelope generators 810 are configured to implement pulse-shaping techniques to generate RF control pulses with desired control pulse envelope shapes (e.g., Gaussian pulses, cosine pulses (e.g., sum of half cosines), hyperbolic secant pulses, etc.), which are applied to superconducting qubits or active qubit coupler circuits to perform single qubit gate operations, entanglement gate operations, etc. The shaped control pulses are calibrated to drive f₀₁ transitions of the qubits, while suppressing f₁₂ and higher transitions. Essentially, such pulse shaping techniques suppress/reduce the transients associated with turning the control pulses on and off. In addition, pulse-shaping techniques include DRAG (derivative removal by adiabatic gate) correction pulses, which can be used in conjunction with shaped pulses (such as Gaussian pulses, cosine pulses, or hyperbolic secant pulses) to further suppress unwanted state transitions, while maintaining a same pulse envelope area (or integral of pulse envelope).

In each AWG channel of the AWG system 802, the digital control pulse envelope signals (digital I and Q components) are converted to analog control pulse envelope signals (analog baseband I/Q signals), and the I/Q mixer stage 840 modulates the quadrature LO signals using the baseband I/Q signals by performing, e.g., SSB modulation, as discussed above, to generate a modulated signal in the form of an RF control pulse that is applied, e.g., on a qubit drive line to control a given qubit. The functions of the various stages 820, 830, 850, 860, 870, and 880 are the same or similar to the corresponding stages in FIG. 1, FIG. 2, etc., the details of which will not be repeated.

As further shown in FIG. 8, in some embodiments, each AWG channel 802-1, . . . , 802-c of the AWG system 802 comprises dedicated calibration circuitry 890-1, . . . , 890-c, which is implemented on-chip with the AWG system 802. The calibration circuitry 890-1, . . . , 890-c is configured to calibrate the respective AWG channels 802-1, . . . , 802-c of the AWG system 802 for different operating modes, as discussed above. The calibration circuitry 890-1, . . . , 890-c comprises the hardware control and logic circuitry (e.g., DC offset compensation DACs, control logic circuitry to generate control signals, etc.) as discussed above. In some embodiments, the calibration circuitry 890-1, . . . , 890-c is controlled by software running on a computing platform that controls the quantum computing system 800.

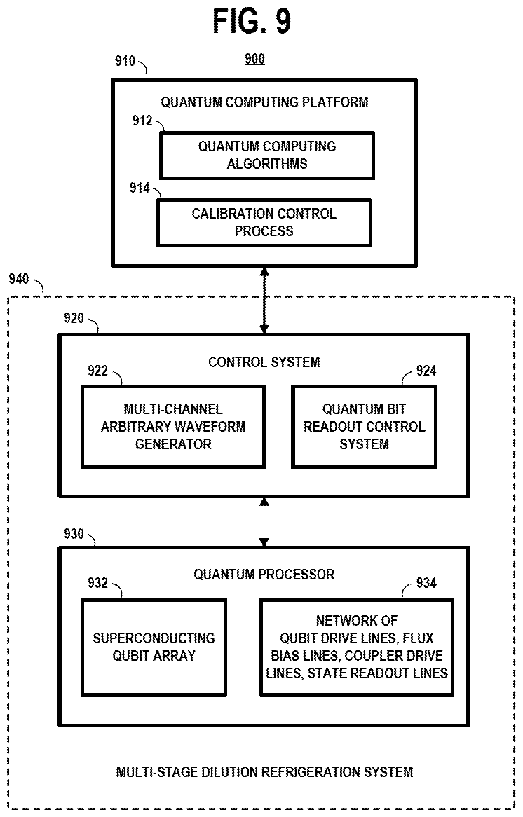

For example, FIG. 9 schematically illustrates a quantum computing system, according to another exemplary embodiment of the disclosure. In particular, FIG. 9 schematically illustrates a quantum computing system 900 which comprises a quantum computing platform 910, a control system 920, and a quantum processor 930. In some embodiments, the quantum computing platform 910 implements software programs such as quantum computing algorithms 912 to perform quantum computing or quantum information process, and a calibration control process 914 which performs functions such as configuring the AWG system, controlling the execution of high-level functions of the calibration processes, etc.

Furthermore, the quantum computing platform 910 executes calibration procedures that are periodically performed on a quantum system such as a quantum processor to calibrate various quantum elements such as readout resonators, data qubits, and coupler circuitry, etc., to enable high-fidelity gate operations (e.g., single-qubit gate operations and entanglement gate operations). For example, various types of in-situ calibration procedures are periodically performed to, e.g., determine the resonant frequencies of readout resonators, determine the transition frequencies of qubits, determine coherence times (T₁) of the qubits (where the coherence time T₁ of a given qubit denotes the time it takes for the qubit state to decay from the excited state to the ground state), determine transverse relaxation times (T₂) of the qubits (or dephasing time), calibrate control pulses that are applied to qubits to perform single-qubit gate operations, calibrate control pulses that are applied to active coupler circuits to perform entanglement gate operations, etc. The calibration procedures result in determining various control parameters that are maintained in a calibration database and periodically updated on the order of seconds, minutes, hours, days, etc., as needed, depending on the type of quantum element and the operating characteristics of the quantum computing system, and other factors as is understood by those of ordinary skill in the art.

In some embodiments, the control system 920 comprises a multi-channel arbitrary waveform generator 922, and a quantum bit readout control system 924, wherein FIG. 8 schematically illustrates an exemplary AWG system 802 which can be implemented in the control system 920. The quantum processor 930 comprises one or more quantum processor chips comprising a superconducting qubit array 932 and a network 934 of qubit drive lines, coupler drive lines, and qubit state readout lines, and other circuit QED components that may be needed for a given application or quantum system configuration.

In some embodiments, the control system 920 and the quantum processor 930 are disposed in a dilution refrigeration system 940 which can generate cryogenic temperatures that are sufficient to operate components of the control system 920 for quantum computing applications. For example, the quantum processor 930 may need to be cooled down to near-absolute zero, e.g., 10-15 millikelvin (mK), to allow the superconducting qubits to exhibit quantum behaviors. In some embodiments, the dilution refrigeration system 940 comprises a multi-stage dilution refrigerator where the components of the control system 920 can be maintained at different cryogenic temperatures, as needed. For example, while the quantum processor 930 may need to be cooled down to, e.g., 10-15 mK, the circuit components of the control system 920 may be operated at cryogenic temperatures greater than 10-15 mK (e.g., cryogenic temperatures in a range of 3K-4K), depending on the configuration of the quantum computing system.

In some embodiments, the superconducting qubit array 932 comprises a plurality of superconducting transmon qubits and superconducting tunable coupler qubits, in which each pair of superconducting qubits is connected by a respective superconducting qubit coupler, using techniques as discussed herein. The network 934 of qubit drive lines, flux bias lines, coupler drive lines, and qubit state readout lines, etc., are configured to apply microwave control signals to superconducting qubits and coupler circuitry in the superconducting qubit array 932 to perform various types of gate operations, e.g., single-gate operations, entanglement gate operations, etc., as well as read the quantum states of the superconducting qubits. The network 934 of qubit drive lines, flux bias lines, coupler drive lines, and qubit state readout lines, etc., is coupled to the control system 920 through a suitable hardware input/output (I/O) interface, which couples I/O signals between the control system 920 and the quantum processor 930. For example, the hardware I/O interface may comprise various types of hardware and components, such as RF cables, wiring, RF elements, optical fibers, heat exchanges, filters, amplifiers, isolators, etc.

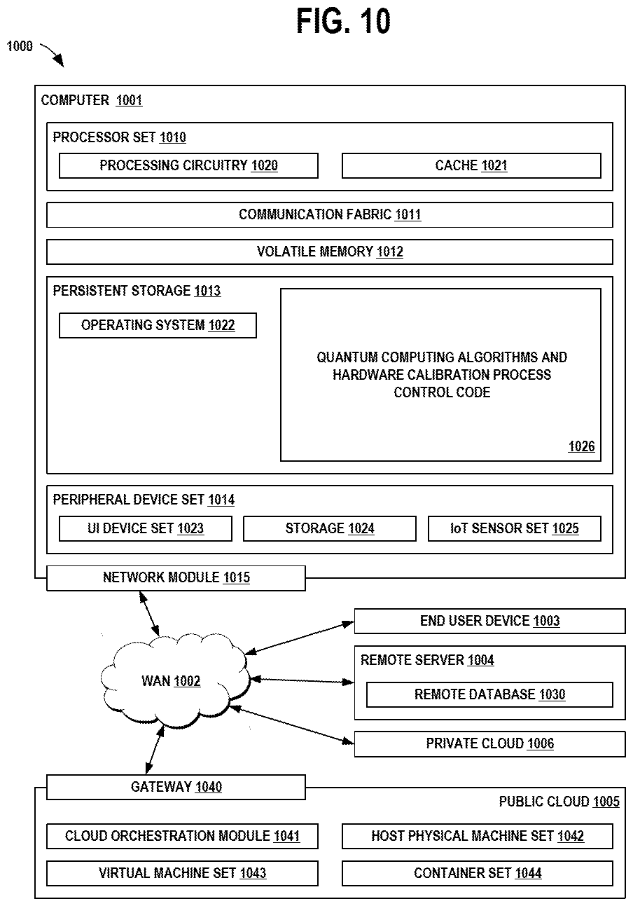

The quantum computing platform 910 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 910 comprises a hardware architecture of processors, memory, etc., which is configured to control the execution of quantum applications, and interface with the control system 920 to (i) generate digital control signals that are converted to analog microwave control signals by the control system 920, to control operations of the quantum processor 930 when executing a given quantum application, and (ii) to obtain and process digital signals received from the control system 920, which represent the processing results generated by the quantum processor 930 when executing various gate operations for a given quantum application. In some exemplary embodiments, the quantum computing platform 910 of the quantum computing system 900 may be implemented using any suitable computing system architecture (e.g., as shown in FIG. 10) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1000 contains an example of an environment for the execution of at least some of the computer code 1026 involved in performing inventive methods, such as quantum computing algorithm code to perform quantum computing or quantum information processing, and hardware calibration process control code to control functions of, e.g., the calibration control system 190 of FIG. 1, and the calibration circuitry 890-1 . . . , 890-c of FIG. 8, etc. In addition to block 1026, computing environment 1000 includes, for example, computer 1001, wide area network (WAN) 1002, end user device (EUD) 1003, remote server 1004, public cloud 1005, and private cloud 1006. In this embodiment, computer 1001 includes processor set 1010 (including processing circuitry 1020 and cache 1021), communication fabric 1011, volatile memory 1012, persistent storage 1013 (including operating system 1022 and block 1026, as identified above), peripheral device set 1014 (including user interface (UI), device set 1023, storage 1024, and Internet of Things (IoT) sensor set 1025), and network module 1015. Remote server 1004 includes remote database 1030. Public cloud 1005 includes gateway 1040, cloud orchestration module 1041, host physical machine set 1042, virtual machine set 1043, and container set 1044.

Computer 1001 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1030. As is well understood in the art of computer technology, and depending upon the technology, performance of a computer-implemented method may be distributed among multiple computers and/or between multiple locations. On the other hand, in this presentation of computing environment 1000, detailed discussion is focused on a single computer, specifically computer 1001, to keep the presentation as simple as possible. Computer 1001 may be located in a cloud, even though it is not shown in a cloud in FIG. 10. On the other hand, computer 1001 is not required to be in a cloud except to any extent as may be affirmatively indicated.

Processor set 1010 includes one, or more, computer processors of any type now known or to be developed in the future. Processing circuitry 1020 may be distributed over multiple packages, for example, multiple, coordinated integrated circuit chips. Processing circuitry 1020 may implement multiple processor threads and/or multiple processor cores. Cache 1021 is memory that is located in the processor chip package(s) and is typically used for data or code that should be available for rapid access by the threads or cores running on processor set 1010. Cache memories are typically organized into multiple levels depending upon relative proximity to the processing circuitry. Alternatively, some, or all, of the cache for the processor set may be located “off chip.” In some computing environments, processor set 1010 may be designed for working with qubits and performing quantum computing.

Computer readable program instructions are typically loaded onto computer 1001 to cause a series of operational steps to be performed by processor set 1010 of computer 1001 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1021 and the other storage media discussed below. The program instructions, and associated data, are accessed by processor set 1010 to control and direct performance of the inventive methods. In computing environment 1000, at least some of the instructions for performing the inventive methods may be stored in block 1026 in persistent storage 1013.

Communication fabric 1011 is the signal conduction paths that allow the various components of computer 1001 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1012 is any type of volatile memory now known or to be developed in the future. Examples include dynamic type random access memory (RAM) or static type RAM. Typically, the volatile memory is characterized by random access, but this is not required unless affirmatively indicated. In computer 1001, the volatile memory 1012 is located in a single package and is internal to computer 1001, but, alternatively or additionally, the volatile memory may be distributed over multiple packages and/or located externally with respect to computer 1001.

Persistent storage 1013 is any form of non-volatile storage for computers that is now known or to be developed in the future. The non-volatility of this storage means that the stored data is maintained regardless of whether power is being supplied to computer 1001 and/or directly to persistent storage 1013. Persistent storage 1013 may be a read only memory (ROM), but typically at least a portion of the persistent storage allows writing of data, deletion of data and re-writing of data. Some familiar forms of persistent storage include magnetic disks and solid-state storage devices. Operating system 1022 may take several forms, such as various known proprietary operating systems or open-source Portable Operating System Interface type operating systems that employ a kernel. The code included in block 1026 typically includes at least some of the computer code involved in performing the inventive methods.

Peripheral device set 1014 includes the set of peripheral devices of computer 1001. Data communication connections between the peripheral devices and the other components of computer 1001 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1023 may include components such as a display screen, speaker, microphone, wearable devices (such as goggles and smart watches), keyboard, mouse, printer, touchpad, game controllers, and haptic devices. Storage 1024 is external storage, such as an external hard drive, or insertable storage, such as an SD card. Storage 1024 may be persistent and/or volatile. In some embodiments, storage 1024 may take the form of a quantum computing storage device for storing data in the form of qubits. In embodiments where computer 1001 is required to have a large amount of storage (for example, where computer 1001 locally stores and manages a large database) then this storage may be provided by peripheral storage devices designed for storing very large amounts of data, such as a storage area network (SAN) that is shared by multiple, geographically distributed computers. IoT sensor set 1025 is made up of sensors that can be used in Internet of Things applications. For example, one sensor may be a thermometer and another sensor may be a motion detector.

Network module 1015 is the collection of computer software, hardware, and firmware that allows computer 1001 to communicate with other computers through WAN 1002. Network module 1015 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1015 are performed on the same physical hardware device. In other embodiments (for example, embodiments that utilize software-defined networking (SDN)), the control functions and the forwarding functions of network module 1015 are performed on physically separate devices, such that the control functions manage several different network hardware devices. Computer readable program instructions for performing the inventive methods can typically be downloaded to computer 1001 from an external computer or external storage device through a network adapter card or network interface included in network module 1015.

WAN 1002 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1003 is any computer system that is used and controlled by an end user (for example, a customer of an enterprise that operates computer 1001), and may take any of the forms discussed above in connection with computer 1001. EUD 1003 typically receives helpful and useful data from the operations of computer 1001. For example, in a hypothetical case where computer 1001 is designed to provide a recommendation to an end user, this recommendation would typically be communicated from network module 1015 of computer 1001 through WAN 1002 to EUD 1003. In this way, EUD 1003 can display, or otherwise present, the recommendation to an end user. In some embodiments, EUD 1003 may be a client device, such as thin client, heavy client, mainframe computer, desktop computer and so on.

Remote server 1004 is any computer system that serves at least some data and/or functionality to computer 1001. Remote server 1004 may be controlled and used by the same entity that operates computer 1001. Remote server 1004 represents the machine(s) that collect and store helpful and useful data for use by other computers, such as computer 1001. For example, in a hypothetical case where computer 1001 is designed and programmed to provide a recommendation based on historical data, then this historical data may be provided to computer 1001 from remote database 1030 of remote server 1004.

Public cloud 1005 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1005 is performed by the computer hardware and/or software of cloud orchestration module 1041. The computing resources provided by public cloud 1005 are typically implemented by virtual computing environments that run on various computers making up the computers of host physical machine set 1042, which is the universe of physical computers in and/or available to public cloud 1005. The virtual computing environments (VCEs) typically take the form of virtual machines from virtual machine set 1043 and/or containers from container set 1044. It is understood that these VCEs may be stored as images and may be transferred among and between the various physical machine hosts, either as images or after instantiation of the VCE. Cloud orchestration module 1041 manages the transfer and storage of images, deploys new instantiations of VCEs and manages active instantiations of VCE deployments. Gateway 1040 is the collection of computer software, hardware, and firmware that allows public cloud 1005 to communicate through WAN 1002.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1006 is similar to public cloud 1005, except that the computing resources are only available for use by a single enterprise. While private cloud 1006 is depicted as being in communication with WAN 1002, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1005 and private cloud 1006 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a differential voltage-mode filter circuit comprising a first voltage-mode filter circuit, a second voltage-mode filter circuit, and a neutralization network, wherein:
the first voltage-mode filter circuit and the second voltage-mode filter circuit each comprise a unity gain buffer having a nonzero output impedance;
the neutralization network comprises a first neutralization impedance circuit which couples an input node of the first voltage-mode filter circuit to an output node of the second voltage-mode filter circuit, and a second neutralization impedance circuit which couples an input node of the second voltage-mode filter circuit to an output node of the first voltage-mode filter circuit; and
the neutralization network is configured to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

2. The device of claim 1, wherein the neutralization network is configured to correct the frequency response of each of the first voltage-mode filter circuit and the second voltage-mode filter circuit by adding at least one transmission pole to the transfer function of each of the first voltage-mode filter circuit and the second voltage-mode filter circuit.

3. The device of claim 1, wherein the first voltage-mode filter circuit and the second voltage-mode filter circuit each comprise a low-pass filter circuit with at least a biquadratic transfer function.

4. The device of claim 1, wherein the first neutralization impedance circuit and the second neutralization impedance circuit each comprise passive impedance elements.

5. The device of claim 1, wherein:
the first neutralization impedance circuit comprises at least a first resistor and a first capacitor serially connected between the input node of the first voltage-mode filter circuit and the output node of the second voltage-mode filter circuit; and
the second neutralization impedance circuit comprises at least a second resistor and a second capacitor serially connected between the input node of the second voltage-mode filter circuit and the output node of the first voltage-mode filter circuit.

6. The device of claim 5, wherein the first capacitor and the second capacitor are variable capacitors.

7. The device of claim 1, wherein the first voltage-mode filter circuit and the second voltage-mode filter circuit each comprise an analog Sallen-Key filter circuit comprising a unity gain source follower.

8. A device, comprising:
a digital-to-analog converter circuit comprising an output interface configured to generate a differential analog voltage signal comprising a first voltage signal and a second voltage signal which are complementary voltage signals;
a differential voltage-mode filter circuit configured to filter the differential analog voltage signal and output a filtered differential analog voltage signal comprising a first filtered voltage signal and a second filtered voltage signal which are complementary filtered voltage signals; and
a current-mode output circuit, coupled to the differential voltage-mode filter circuit, and configured to convert the first filtered voltage signal and the second filtered voltage signal into a first current signal and a second current signal, respectively, for processing by the current-mode output circuit;
wherein the differential voltage-mode filter circuit comprises a first voltage-mode filter circuit configured to filter the first voltage signal, a second voltage-mode filter circuit configured to filter the second voltage signal, and a neutralization network comprising a first neutralization impedance circuit and a second neutralization impedance circuit;
wherein the first voltage-mode filter circuit and the second voltage-mode filter circuit each comprise a unity gain buffer having a nonzero output impedance;
wherein the first neutralization impedance circuit couples an input node of the first voltage-mode filter circuit to an output node of the second voltage-mode filter circuit, and the second neutralization impedance circuit couples an input node of the second voltage-mode filter circuit to an output node of the first voltage-mode filter circuit; and
wherein the neutralization network is configured to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

9. The device of claim 8, wherein the current-mode output circuit comprises:
a first input transistor which comprises a gate terminal coupled to the output node of the first voltage-mode filter circuit and a source terminal coupled to a regulated voltage node;
a second input transistor which comprises a gate terminal coupled to the output node of the second voltage-mode filter circuit and a source terminal coupled to the regulated voltage node;
a regulation circuit configured to adjust a voltage level on the regulated voltage node to maintain a constant gate-source bias voltage for the first input transistor and the second input transistor to generate currents for biasing the current-mode output circuit.

10. The device of claim 8, wherein the neutralization network is configured to correct the frequency response of each of the first voltage-mode filter circuit and the second voltage-mode filter circuit by adding at least one transmission pole to the transfer function of each of the first voltage-mode filter circuit and the second voltage-mode filter circuit.

11. The device of claim 8, wherein the first voltage-mode filter circuit and the second voltage-mode filter circuit each comprise a low-pass filter circuit with at least a biquadratic transfer function.

12. The device of claim 8, wherein the first neutralization impedance circuit and the second neutralization impedance circuit each comprise passive impedance elements.

13. The device of claim 8, wherein:
the first neutralization impedance circuit comprises at least a first resistor and a first capacitor serially connected between the input node of the first voltage-mode filter circuit and the output node of the second voltage-mode filter circuit;
the second neutralization impedance circuit comprises at least a second resistor and a second capacitor serially connected between the input node of the second voltage-mode filter circuit and the output node of the first voltage-mode filter circuit; and
the first capacitor and the second capacitor are one of fixed capacitors and variable capacitors.

14. The device of claim 8, wherein the first voltage-mode filter circuit and the second voltage-mode filter circuit each comprise an analog Sallen-Key filter circuit which comprises a unity gain source follower.

15. A system, comprising:
a radio frequency signal generator which is configured to convert a baseband signal to a radio frequency signal, the radio frequency signal generator comprising:
a digital-to-analog converter circuit comprising an output interface configured to generate a differential baseband voltage signal comprising a first baseband voltage signal and a second baseband voltage signal which are complementary baseband voltage signals;
a differential voltage-mode filter circuit configured to filter the differential baseband voltage signal and output a filtered differential baseband voltage signal comprising a first filtered baseband voltage signal and a second filtered baseband voltage signal which are complementary filtered baseband voltage signals; and
a current-mode radio frequency output circuit, coupled to the differential voltage-mode filter circuit, and configured to convert the first filtered baseband voltage signal and the second filtered baseband voltage signal into a first baseband current signal and a second baseband current signal, respectively, for processing by the current-mode radio frequency output circuit to generate the radio frequency signal;
wherein the differential voltage-mode filter circuit comprises a first voltage-mode filter circuit configured to filter the first baseband voltage signal, a second voltage-mode filter circuit configured to filter the second baseband voltage signal, and a neutralization network comprising a first neutralization impedance circuit and a second neutralization impedance circuit;
wherein the first voltage-mode filter circuit and the second voltage-mode filter circuit each comprise a unity gain buffer having a nonzero output impedance;
wherein the first neutralization impedance circuit couples an input node of the first voltage-mode filter circuit to an output node of the second voltage-mode filter circuit, and the second neutralization impedance circuit couples an input node of the second voltage-mode filter circuit to an output node of the first voltage-mode filter circuit; and
wherein the neutralization network is configured to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

16. The system of claim 15, wherein the neutralization network is configured to correct the frequency response of each of the first voltage-mode filter circuit and the second voltage-mode filter circuit by adding at least one transmission pole to the transfer function of each of the first voltage-mode filter circuit and the second voltage-mode filter circuit.

17. The system of claim 15, wherein the first voltage-mode filter circuit and the second voltage-mode filter circuit each comprise a low-pass filter circuit with at least a biquadratic transfer function.

18. The system of claim 15, wherein:
the first neutralization impedance circuit comprises at least a first resistor and a first capacitor serially connected between the input node of the first voltage-mode filter circuit and the output node of the second voltage-mode filter circuit;
the second neutralization impedance circuit comprises at least a second resistor and a second capacitor serially connected between the input node of the second voltage-mode filter circuit and the output node of the first voltage-mode filter circuit;
wherein the first capacitor and the second capacitor are one of fixed capacitors and variable capacitors.

19. The system of claim 15, wherein the first voltage-mode filter circuit and the second voltage-mode filter circuit each comprise an analog Sallen-Key filter circuit which comprises a unity gain source follower.

20. A system, comprising:
a quantum processor comprising at least one superconducting quantum bit;
an arbitrary waveform generator comprising at least one arbitrary waveform generator channel configured to convert a baseband signal to a radio frequency control pulse which controls the at least one superconducting quantum bit, wherein the at least one arbitrary waveform generator channel comprises:
a digital-to-analog converter circuit comprising an output interface configured to generate a differential baseband voltage signal comprising a first baseband voltage signal and a second baseband voltage signal which are complementary baseband voltage signals;
a differential voltage-mode filter circuit configured to filter the differential baseband voltage signal and output a filtered differential baseband voltage signal comprising a first filtered baseband voltage signal and a second filtered baseband voltage signal which are complementary filtered baseband voltage signals; and
a current-mode radio frequency output circuit, coupled to the differential voltage-mode filter circuit, and configured to convert the first filtered baseband voltage signal and the second filtered baseband voltage signal into a first baseband current signal and a second baseband current signal, respectively, for processing by the current-mode radio frequency output circuit to generate the radio frequency control pulse;
wherein the differential voltage-mode filter circuit comprises a first voltage-mode filter circuit configured to filter the first baseband voltage signal, a second voltage-mode filter circuit configured to filter the second baseband voltage signal, and a neutralization network comprising a first neutralization impedance circuit and a second neutralization impedance circuit;
wherein the first voltage-mode filter circuit and the second voltage-mode filter circuit each comprise a unity gain buffer having a nonzero output impedance;
wherein the first neutralization impedance circuit couples an input node of the first voltage-mode filter circuit to an output node of the second voltage-mode filter circuit, and the second neutralization impedance circuit couples an input node of the second voltage-mode filter circuit to an output node of the first voltage-mode filter circuit; and
wherein the neutralization network is configured to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.

21. The system of claim 20, wherein the neutralization network is configured to correct the frequency response of each of the first voltage-mode filter circuit and the second voltage-mode filter circuit by adding at least one transmission pole to the transfer function of each of the first voltage-mode filter circuit and the second voltage-mode filter circuit.

22. The system of claim 20, wherein the first voltage-mode filter circuit and the second voltage-mode filter circuit each comprise a low-pass filter circuit with at least a biquadratic transfer function.

23. The system of claim 20, wherein:
the first neutralization impedance circuit comprises at least a first resistor and a first capacitor serially connected between the input node of the first voltage-mode filter circuit and the output node of the second voltage-mode filter circuit;
the second neutralization impedance circuit comprises at least a second resistor and a second capacitor serially connected between the input node of the second voltage-mode filter circuit and the output node of the first voltage-mode filter circuit;
wherein the first capacitor and the second capacitor are one of fixed capacitors and variable capacitors.

24. The system of claim 20, wherein the first voltage-mode filter circuit and the second voltage-mode filter circuit each comprise an analog Sallen-Key filter circuit which comprises a unity gain source follower.

25. A method, comprising:
applying a differential voltage signal to a first input node and a second input node of a differential voltage-mode filter circuit to generate a filtered differential signal on a first output node and a second output node of the differential voltage-mode filter circuit, wherein the differential voltage-mode filter circuit comprises a first voltage-mode filter circuit and a second voltage-mode filter circuit each comprising a unity gain buffer having a nonzero output impedance, and a neutralization network comprising a first neutralization impedance circuit which couples an input node of the first voltage-mode filter circuit to an output node of the second voltage-mode filter circuit, and a second neutralization impedance circuit which couples an input node of the second voltage-mode filter circuit to an output node of the first voltage-mode filter circuit; and
configuring the neutralization network to correct a frequency response of each of the first voltage-mode filter circuit and the second voltage-mode filter circuit by at least one of cancelling and compensating for at least one transmission zero of a transfer function of each of the first voltage-mode filter circuit and the second voltage-mode filter circuit, which results from the nonzero output impedance of the respective unity gain buffers.
